(19) United States
(12) Patent Application Publication
(10) Pub. No.: US 2026/0023137 A1
(43) Pub. Date: Jan. 22, 2026

(54) MAGNETIC SENSOR AND MANUFACTURING METHOD FOR THE SAME

(71) Applicant: TDK CORPORATION, Tokyo (JP)

(72) Inventors: Norikazu OTA, Tokyo (JP); Hiraku HIRABAYASHI, Tokyo (JP); Keisuke TAKASUGI, Tokyo (JP)

(73) Assignee: TDK CORPORATION, Tokyo (JP)

(21) Appl. No.: 19/262,310

(22) Filed: Jul. 8, 2025

(30) Foreign Application Priority Data
Jul. 17, 2024 (JP) 2024-114088

(51) Int. Cl. G01R 33/09; G01R 33/00

(52) U.S. Cl. CPC G01R 33/091; G01R 33/0052; G01R 33/093; G01R 33/098

(57) ABSTRACT

A magnetic sensor includes a plurality of yokes, a plurality of MR elements, and a plurality of bridge circuits. The plurality of yokes include a plurality of first yokes disposed at a same position in a first direction. The plurality of bridge circuits include a first bridge circuit and a second bridge circuit that are disposed at positions different from each other in the first direction, and disposed so that the plurality of first yokes are interposed therebetween. The first bridge circuit and the second bridge circuit are connected in parallel with each other.

### CROSS REFERENCE TO RELATED APPLICATIONS

This application claims the benefit of Japanese Priority Patent Application No. 2024-114088 filed on Jul. 17, 2024, the entire contents of which are incorporated herein by reference.

### BACKGROUND

The disclosure relates to a magnetic sensor including a plurality of yokes and a plurality of magnetoresistive elements, and a manufacturing method for the magnetic sensor.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer, a direction of magnetization of which is fixed, a free layer, a direction of magnetization of which is variable depending on the direction of an applied magnetic field, and a gap layer disposed between the magnetization pinned layer and the free layer.

A type of magnetic sensor is known that includes a yoke formed of a soft magnetic material near a magnetoresistive element. The yoke is used to increase the strength of the applied magnetic field or convert the direction of the applied magnetic field. JP 2012-127736 A, for example, discloses a technology of sandwiching a magnetoresistive element by a pair of magnetic films formed of a soft magnetic material. The pair of magnetic films increases the strength of the magnetic field that the magnetoresistive element receives.

In addition, JP 2019-174196 A discloses a technology of converting a magnetic field in a direction perpendicular to a surface of a substrate into a magnetic field in a direction parallel to the surface of the substrate with a plurality of yokes, to apply the converted magnetic field to a plurality of magnetoresistive elements. Each of the plurality of yokes has a shape that is long in one direction, and receives an input magnetic field and generates an output magnetic field. The plurality of magnetoresistive elements are arranged so that several magnetoresistive elements are located on both sides of each of the plurality of yokes. The magnetic sensor includes a wiring section that connects the several magnetoresistive elements, which are arranged along the longitudinal direction of each of the plurality of yokes, in series.

An effective way of increasing the sensitivity of the magnetic sensor is to increase the occupancy area of the magnetoresistive elements (total area of the magnetoresistive elements) in the magnetic sensor. Meanwhile, with the miniaturization of devices to which magnetic sensors are mounted, there has also been a demand for miniaturization of the magnetic sensors. An intension for increasing the occupancy area of the magnetoresistive elements or miniaturizing the magnetic sensor has resulted in an increase in the length and a decrease in the width of the wiring for electrically connecting the plurality of magnetoresistive elements. This has caused problems such as an increased wiring resistance and a drop in the sensitivity of the magnetic sensor. Such problems are particularly pronounced if the magnetic sensor includes wiring that connects a plurality of magnetoresistive elements that are disposed along a structure long in one direction, like a yoke, in series.

Furthermore, in a magnetic sensor including a plurality of yokes, if the occupancy area of the magnetoresistive elements is increased, the number of the magnetoresistive elements increases, which results also in an increase in the number of yokes. As a result, the size of the magnetic sensor including the plurality of yokes increases, compared to a magnetic sensor including no yoke. Such a size increase of the magnetic sensor has problematically decreased the number of magnetic sensors created from one wafer and increased the cost of the magnetic sensor including the plurality of yokes.

### SUMMARY

A magnetic sensor according to one embodiment of the disclosure includes: a plurality of yokes each formed of a soft magnetic material; a plurality of magnetoresistive elements configured to detect a magnetic field induced by the plurality of yokes; and a plurality of bridge circuits constituted of the plurality of magnetoresistive elements, each of the plurality of bridge circuits being configured to generate at least one detection signal. The plurality of yokes include a plurality of first yokes disposed at a same position in a first direction. The plurality of bridge circuits include a first bridge circuit and a second bridge circuit that are disposed at positions different from each other in the first direction, and disposed so that the plurality of first yokes are interposed between the first bridge circuit and the second bridge circuit. The first bridge circuit and the second bridge circuit are connected in parallel with each other.

Objects, features, and advantages of the disclosure will appear more fully from the following description.

### BRIEF DESCRIPTION OF THE DRAWINGS

The accompanying drawings are included to provide an understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is an explanatory diagram schematically showing the magnetic sensor according to the first example embodiment of the disclosure.

FIG. 3 is a circuit diagram showing a circuit configuration of the magnetic sensor according to the first example embodiment of the disclosure.

FIG. 4 is a perspective view showing a part of the magnetic sensor according to the first example embodiment of the disclosure.

FIG. 5 is a side view showing a part of the magnetic sensor according to the first example embodiment of the disclosure.

FIG. 6 is a plan view showing a part of the magnetic sensor according to the first example embodiment of the disclosure.

FIG. 7 is a perspective view showing a magnetoresistive element in the first example embodiment of the disclosure.

FIG. 8 is a circuit diagram showing a circuit configuration of a magnetic sensor according to a second example embodiment of the disclosure.

FIG. 9 is a perspective view showing a part of the magnetic sensor according to the second example embodiment of the disclosure.

FIG. 10 is a side view showing a part of the magnetic sensor according to the second example embodiment of the disclosure.

FIG. 11 is a plan view showing a part of the magnetic sensor according to the second example embodiment of the disclosure.

FIG. 12 is a circuit diagram showing a circuit configuration of a magnetic sensor according to a third example embodiment of the disclosure.

FIG. 13 is a perspective view showing a part of the magnetic sensor according to the third example embodiment of the disclosure.

FIG. 14 is a side view showing a part of the magnetic sensor according to the third example embodiment of the disclosure.

FIG. 15 is a plan view showing a part of the magnetic sensor according to the third example embodiment of the disclosure.

FIG. 16 is an explanatory diagram showing directions of magnetization of magnetization pinned layers in first and third resistor sections in the third example embodiment of the disclosure.

FIG. 17 is an explanatory diagram showing directions of magnetization of magnetization pinned layers in second and fourth resistor sections in the third example embodiment of the disclosure.

FIG. 18 is a perspective view showing a part of a magnetic sensor according to a fourth example embodiment of the disclosure.

FIG. 19 is a side view showing a part of the magnetic sensor according to the fourth example embodiment of the disclosure.

FIG. 20 is a circuit diagram showing a circuit configuration of a magnetic sensor according to a fifth example embodiment of the disclosure.

FIG. 21 is an explanatory diagram showing directions of magnetization of magnetization pinned layers in first and third resistor sections in the fifth example embodiment of the disclosure.

FIG. 22 is an explanatory diagram showing directions of magnetization of magnetization pinned layers in second and fourth resistor sections in the fifth example embodiment of the disclosure.

FIG. 23 is a side view showing a part of a modification example of the magnetic sensor according to the fifth example embodiment of the disclosure.

FIG. 24 is a perspective view showing a yoke in a sixth example embodiment of the disclosure.

FIG. 25 is a side view showing a modification example of the yoke in the sixth example embodiment of the disclosure.

### DETAILED DESCRIPTION

An object of the disclosure is to provide a magnetic sensor that is capable of increasing an occupancy area of a plurality of magnetoresistive elements while decreasing a resistance of a wiring that electrically connects the plurality of magnetoresistive elements.

In the following, some example embodiments and modification examples of the disclosure are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Furthermore, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions.

### First Example Embodiment

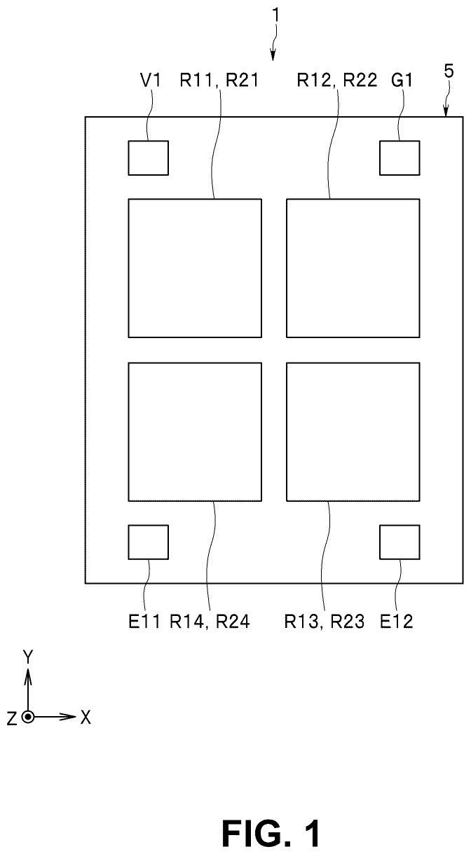

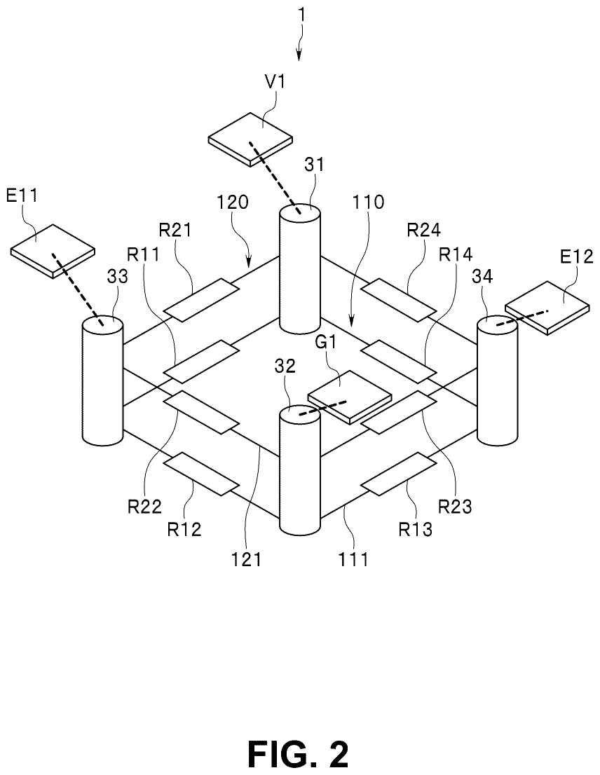

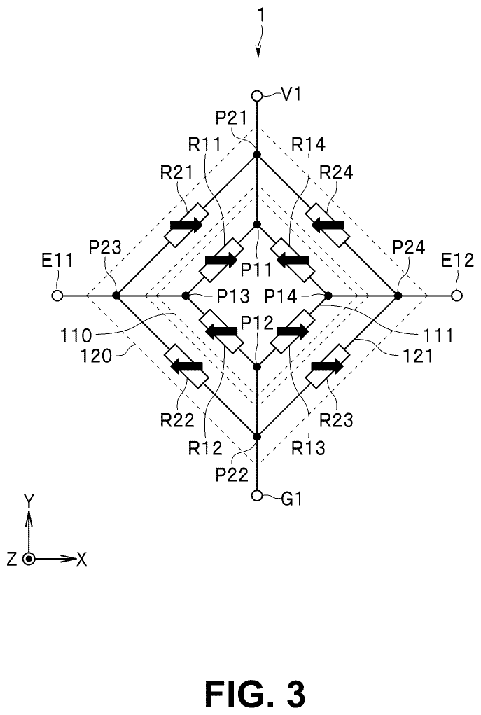

First, a schematic configuration of a magnetic sensor 1 according to a first example embodiment of the disclosure will be described with reference to FIGS. 1 to 3. FIG. 1 is a plan view showing the magnetic sensor 1. FIG. 2 is an explanatory diagram schematically showing the magnetic sensor 1. FIG. 3 is a circuit diagram showing a circuit configuration of the magnetic sensor 1.

The magnetic sensor 1 according to the example embodiment is used as a part of a geomagnetic sensor, for example. The magnetic sensor 1 includes a plurality of magnetoresistive elements 50, and a plurality of bridge circuits constituted of the plurality of magnetoresistive elements 50. Each of a plurality of bridge circuits is configured to generate at least one detection signal. The magnetoresistive elements 50 will hereinafter be referred to as MR elements 50.

In the example embodiment, the magnetic sensor 1 includes a first bridge circuit 110 and a second bridge circuit 120 as a plurality of bridge circuits. The first bridge circuit 110 and the second bridge circuit 120 are connected in parallel with each other. The first bridge circuit 110 may include a first resistor section R11, a second resistor section R12, a third resistor section R13, and a fourth resistor section R14. The second bridge circuit 120 may include a first resistor section R21, a second resistor section R22, a third resistor section R23, and a fourth resistor section R24. Each of the resistor sections R11 to R14, and R21 to R24 is configured by several MR elements 50 of the plurality of MR elements 50 being electrically connected.

As shown in FIG. 1, the magnetic sensor 1 further includes a substrate 5. The resistor sections R11 to R14 and R21 to R24 are provided on the substrate 5.

Here, as shown in FIG. 1, an X direction, a Y direction, and a Z direction are defined. The X direction, the Y direction, and the Z direction are orthogonal to one another. The opposite directions to the X, Y, and Z directions will be expressed as −X, −Y, and −Z directions, respectively. In the example embodiment, in particular, a direction perpendicular to the surface of the substrate 5 is referred to as the Z direction.

As used herein, the term “above” refers to positions located forward of a certain reference position in the Z direction, and “below” refers to positions opposite from the “above” positions with respect to the certain reference position. For each component of the magnetic sensor 1 and for each component of magnetic sensors according to other example embodiments, the term “top surface” refers to a surface of the component lying at the end thereof in the Z direction, and “bottom surface” refers to a surface of the component lying at the end thereof in the −Z direction. The expression “when viewed in a specific direction (e.g., the Z direction)” means that an object is viewed from a position away in the specific direction or in one direction parallel to the specific direction.

Each of the first bridge circuit 110 and the second bridge circuit 120 is configured to detect a magnetic field component of a magnetic field to be detected in a direction parallel to the X direction, and generate at least one detection signal having a correspondence with a strength of the magnetic field component.

Next, a layout of the resistor sections R11 to R14 and R21 to R24 will be described with reference to FIG. 1. FIG. 1 shows an example of the layout of the resistor sections R11 to R14 and R21 to R24 on the substrate 5. The rectangular region denoted by the reference numerals R11, R21 in FIG. 1 shows a region where the first resistor sections R11 and R21 are disposed. In the example embodiment, the first bridge circuit 110 and the second bridge circuit 120 are disposed at positions different from each other in a direction parallel to the Z direction. The first resistor section R11 and the first resistor section R21 are thus disposed at the positions different from each other in the direction parallel to the Z direction in the rectangular region denoted by the reference numerals R11, R21. In addition, the first resistor section R11 and the first resistor section R21 may be disposed so as to overlap each other when viewed in the Z direction. The first resistor section R21 may be disposed above the first resistor section R11.

Similarly, the rectangular region denoted by the reference numerals R12, R22 in FIG. 1 shows a region where the second resistor sections R12 and R22 are disposed. The second resistor section R12 and the second resistor section R22 are disposed at positions different from each other in the direction parallel to the Z direction in the rectangular region denoted by the reference numerals R12, R22. In addition, the second resistor section R12 and the second resistor section R22 may be disposed so as to overlap each other when viewed in the Z direction. The second resistor section R22 may be disposed above the second resistor section R12.

Similarly, the rectangular region denoted by the reference numerals R13, R23 in FIG. 1 shows a region where the third resistor sections R13 and R23 are disposed. The third resistor section R13 and the third resistor section R23 are disposed at positions different from each other in the direction parallel to the Z direction in the rectangular region denoted by the reference numerals R13, R23. In addition, the third resistor section R13 and the third resistor section R23 may be disposed so as to overlap each other when viewed in the Z direction. The third resistor section R23 may be disposed above the third resistor section R13.

Similarly, the rectangular region denoted by the reference numerals R14, R24 in FIG. 1 shows a region where the fourth resistor sections R14 and R24 are disposed. The fourth resistor section R14 and the fourth resistor section R24 are disposed at positions different from each other in the direction parallel to the Z direction in the rectangular region denoted by the reference numerals R14, R24. In addition, the fourth resistor section R14 and the fourth resistor section R24 may be disposed so as to overlap each other when viewed in the Z direction. The fourth resistor section R24 may be disposed above the fourth resistor section R14.

In the example shown in FIG. 1, the first and second resistor sections R11 and R12 (the first and second resistor sections R21 and R22) are arranged in a direction parallel to the X direction, along an end portion of the substrate 5 in the Y direction. The second resistor section R12 (the second resistor section R22) is disposed forward of the first resistor section R11 (the first resistor section R21) in the X direction.

The third and fourth resistor sections R13 and R14 (the third and fourth resistor sections R23 and R24) are arranged in the direction parallel to the X direction, along an end portion of the substrate 5 in the −Y direction. The fourth resistor section R14 (the fourth resistor section R24) is disposed forward of the third resistor section R13 (the third resistor section R23) in the −X direction. The third resistor section R13 (the third resistor section R23) is disposed forward of the second resistor section R12 (the second resistor section R22) in the −Y direction. The fourth resistor section R14 (the fourth resistor section R24) is disposed forward of the first resistor section R11 (the first resistor section R21) in the −Y direction.

Note that the layout of the resistor sections R11 to R14 and R21 to R24 on the substrate 5 is not limited to the example shown in FIG. 1. For example, the first to fourth resistor sections R11 to R14 (the first to fourth resistor sections R21 to R24) may be disposed in a specific order in the direction parallel to the X direction or in a direction parallel to the Y direction.

Next, a connection relationship among the plurality of components of the magnetic sensor 1 will be described with reference to FIGS. 1 to 3. One end of each of the first and fourth resistor sections R11 and R14 is connected to a connection point P11. One end of each of the second and third resistor sections R12 and R13 is connected to a connection point P12. The other end of each of the first and second resistor sections R11 and R12 is connected to a connection point P13. The other end of each of the third and fourth resistor sections R13 and R14 is connected to a connection point P14.

One end of each of the first and fourth resistor sections R21 and R24 is connected to a connection point P21. One end of each of the second and third resistor sections R22 and R23 is connected to a connection point P22. The other end of each of the first and second resistor sections R21 and R22 is connected to a connection point P23. The other end of each of the third and fourth resistor sections R23 and R24 is connected to a connection point P24.

The magnetic sensor 1 may further include a power supply terminal V1, a ground terminal G1, a first signal output terminal E11, and a second signal output terminal E12. As shown in FIG. 1, the power supply terminal V1, the ground terminal G1, the first signal output terminal E11, and the second signal output terminal E12 are provided on the substrate 5. The connection points P11 and P21 are connected to the power supply terminal V1. The connection points P12 and P22 are connected to the ground terminal G1. The connection points P13 and P23 are connected to the first signal output terminal E11. The connection points P14 and P24 are connected to the second signal output terminal E12.

The first resistor sections R11 and R21 are disposed between the power supply terminal V1 and the first signal output terminal E11 in a circuit configuration. In addition, the first resistor sections R11 and R21 are connected in parallel with each other in the circuit configuration. Note that, in the application, the expression “in the (a) circuit configuration” is used to indicate a layout in a circuit diagram, not a layout in a physical configuration.

The second resistor sections R12 and R22 are disposed between the ground terminal G1 and the first signal output terminal E11 in the circuit configuration. In addition, the second resistor sections R12 and R22 are connected in parallel with each other in the circuit configuration.

The third resistor sections R13 and R23 are disposed between the ground terminal G1 and the second signal output terminal E12 in the circuit configuration. The third resistor sections R13 and R23 are connected in parallel with each other in the circuit configuration.

The fourth resistor sections R14 and R24 are disposed between the power supply terminal V1 and the second signal output terminal E12 in the circuit configuration. In addition, the fourth resistor sections R14 and R24 are connected in parallel with each other in the circuit configuration.

The magnetic sensor 1 may further include a connection electrode 31 connected to the power supply terminal V1, a connection electrode 32 connected to the ground terminal G1, a connection electrode 33 connected to the first signal output terminal E11, and a connection electrode 34 connected to the second signal output terminal E12. At least a part of each of the connection electrodes 31 to 34 extends in the direction parallel to the Z direction. The number of the connection electrodes 31 to 34 may be equal to the total number of the power supply terminal V1, the ground terminal G1, the first signal output terminal E11, and the second signal output terminal E12.

Here, among the plurality of MR elements 50, the MR elements included in the first bridge circuit 110 are denoted by the reference numeral 50A, and the MR elements included in the second bridge circuit 120 are denoted by the reference numeral 50B. Note that any given MR element will be denoted by the reference numeral 50. The first bridge circuit 110 may further include a first wiring 111 configure to electrically connect the plurality of MR elements 50A. The second bridge circuit 120 may further include a second wiring 121 configure to electrically connect the plurality of MR elements 50B. The connection electrodes 31 to 34 may electrically connect the power supply terminal V1, the ground terminal G1, the first signal output terminal E11, the second signal output terminal E12, the first wiring 111, and the second wiring 121. Thereby, the first and second bridge circuits 110 and 120 are electrically connected to the power supply terminal V1, the ground terminal G1, the first signal output terminal E11, and the second signal output terminal E12.

The connection point P11 is a part of the first wiring 111 which is physically connected to the connection electrode 31. The connection point P12 is a part of the first wiring 111 which is physically connected to the connection electrode 32. The connection point P13 is a part of the first wiring 111 which is physically connected to the connection electrode 33. The connection point P14 is a part of the first wiring 111 which is physically connected to the connection electrode 34.

The connection point P21 is a part of the second wiring 121 which is physically connected to the connection electrode 31. The connection point P22 is a part of the second wiring 121 which is physically connected to the connection electrode 32. The connection point P23 is a part of the second wiring 121 which is physically connected to the connection electrode 33. The connection point P24 is a part of the second wiring 121 which is physically connected to the connection electrode 34.

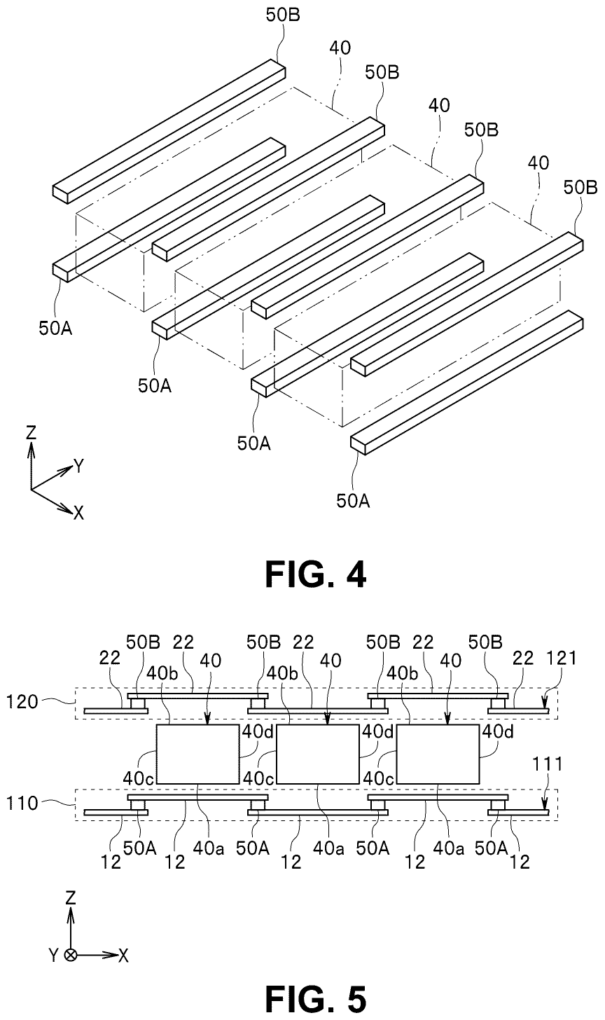

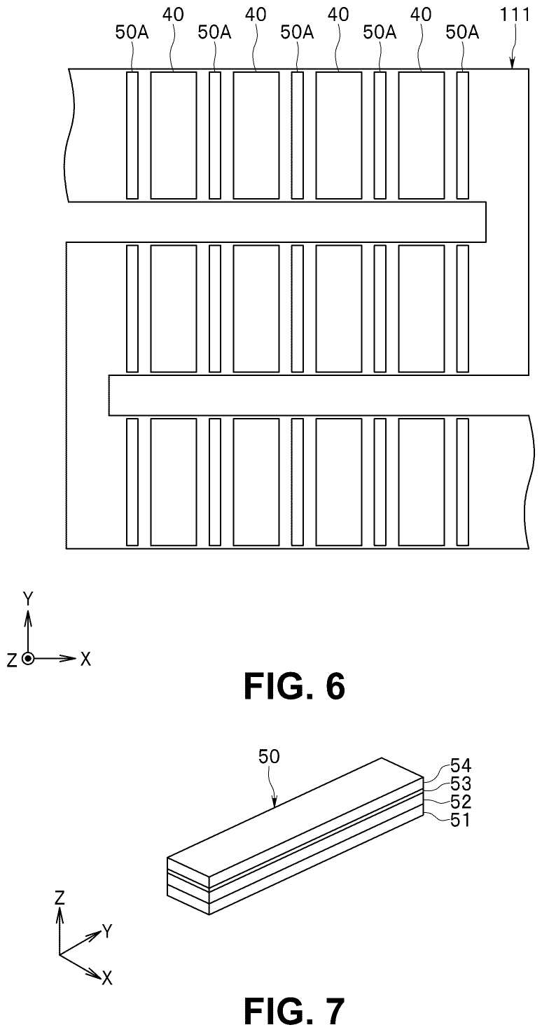

Next, the configurations of the first and second bridge circuits 110 and 120 will be described in detail with reference to FIGS. 4 to 6. FIG. 4 is a perspective view showing a part of the magnetic sensor 1. FIG. 5 is a side view showing a part of the magnetic sensor 1. FIG. 6 is a plan view showing a part of the magnetic sensor 1.

The magnetic sensor 1 further includes a plurality of yokes each formed of a soft magnetic material. The plurality of yokes include a plurality of first yokes 40 disposed at the same position in the direction parallel to the Z direction. In the example embodiment, the plurality of first yokes 40 are configured to induce a magnetic field around the plurality of first yokes 40 and increase a strength of a magnetic field component of the magnetic field to be detected in the X direction, the magnetic field to be detected being applied to the plurality of MR elements 50. Each of the plurality of first yokes 40 has a rectangular parallelepiped shape that is long in the direction parallel to the Y direction. In addition, each of the plurality of first yokes 40 may have a bottom surface 40a and a top surface 40b that are located on opposite sides to each other in the direction parallel to the Z direction, and a first end face 40c and a second end face 40d located on opposite sides to each other in the direction parallel to the X direction.

Note that an example of an aspect in which the plurality of first yokes 40 are disposed at the same position in the direction parallel to the Z direction is not limited to the case where both the bottom surfaces 40a of the respective plurality of first yokes 40 and the top surfaces 40b of the respective plurality of first yokes 40 are disposed at the same position in the direction parallel to the Z direction. For example, even in the case where the bottom surfaces 40a (or the top surfaces 40b) of the respective plurality of first yokes 40 are disposed at positions different from each other in the Z direction, when a virtual plane perpendicular to the Z direction intersects all the plurality of first yokes 40, it can be said that the plurality of first yokes 40 are disposed at the same position in the direction parallel to the Z direction. In such a case, the cross-sectional shapes of the respective plurality of first yokes 40 in a cross section parallel to an XZ plane may be the same or different from one another. The above description of the plurality of first yokes 40 also applies to a description of other plurality of yokes in other example embodiments.

The plurality of MR elements 50 are configured to be capable of detecting the magnetic field induced by the plurality of yokes, and disposed near the plurality of first yokes 40. In the example embodiment, in particular, each of the plurality of MR elements 50 is configured to detect the magnetic field component of the magnetic field to be detected in the X direction, the magnetic field to be detected including the magnetic field induced by the plurality of yokes. The first bridge circuit 110 and the second bridge circuit 120 are disposed so that the plurality of first yokes 40 are interposed therebetween. In the example embodiment, the first bridge circuit 110 is disposed below the plurality of first yokes 40. The second bridge circuit 120 is disposed above the plurality of first yokes 40. Each of the plurality of MR elements 50A is disposed near the bottom surface 40a of each of the plurality of first yokes 40. Each of the plurality of MR elements 50B is disposed near the top surface 40b of each of the plurality of first yokes 40.

The plurality of MR elements 50 may include a plurality of element pairs. Each of the plurality of element pairs may include a first MR element disposed near the first end face 40c of one first yoke 40 and a second MR element disposed near the second end face 40d of the same one first yoke 40. The first MR element corresponds to “first element” in the disclosure. The second MR element corresponds to “second element” in the disclosure. The first MR element and the second MR element included in one element pair are disposed so that one first yoke is interposed between the first MR element and the second MR element when viewed in one direction parallel to the Z direction. In addition, both the first MR element and the second MR element included in one element pair are included in either the first bridge circuit 110 or the second bridge circuit 120.

Here, among the plurality of first yokes 40, focus is placed on two first yokes 40 adjacent at a distance from each other in the direction parallel to the X direction. When viewed in the Z direction, one MR element 50A and one MR element 50B are disposed between the two first yokes 40. The one MR element 50A is disposed at a position that is near the second end face 40d of the first yoke 40 located on the −X direction side of the MR element 50A and near the first end face 40c of the first yoke 40 located on the X direction side of the MR element 50A. Thus, the one MR element 50A corresponds to the second MR element, with the first yoke 40 located on the −X direction side of the MR element 50A as a reference, and corresponds to the first MR element, with the first yoke 40 located on the X direction side of the MR element 50A as a reference.

Similarly, the one MR element 50B is disposed at a position that is near the second end face 40d of the first yoke 40 located on the −X direction side of the MR element 50B and near the first end face 40c of the first yoke 40 located on the X direction side of the MR element 50B. Thus, the one MR element 50B corresponds to the second MR element, with the first yoke 40 located on the −X direction side of the MR element 50B as a reference, and corresponds to the first MR element, with the first yoke 40 located on the X direction side of the MR element 50B as a reference.

Here, among the plurality of element pairs, an element pair constituted of the first and second MR elements disposed near the bottom surface 40a of the first yoke 40 is referred to as a first element pair, and an element pair constituted of the first and second MR elements disposed near the top surface 40b of the first yoke 40 is referred to as a second element pair. The first bridge circuit 110 includes a plurality of first element pairs. The second bridge circuit 120 includes a plurality of second element pairs. The first MR element of the first element pair and the first MR element of the second element pair that are disposed near the one first yoke 40 may overlap each other when viewed in the Z direction. Similarly, the second MR element of the first element pair and the second MR element of the second element pair that are disposed near the one first yoke 40 may overlap each other when viewed in the Z direction.

The first wiring 111 of the first bridge circuit 110 includes a plurality of leads 12 each formed of a conductive material. Each of the plurality of leads 12 electrically connects the first MR element and the second MR element of each of the plurality of first element pairs. Each of the plurality of leads 12 may include a part overlapping the first yoke 40 when viewed in the Z direction. More specifically, each of the plurality of leads 12 extends to pass below the first yoke 40 and connects the first MR element and the second MR element. In the example embodiment, in particular, each of the plurality of leads 12 connects the two MR elements 50A arranged in the direction parallel to the X direction. The dimension of the lead 12 in the direction parallel to the Y direction may be greater than that of the MR element 50A in the direction parallel to the Y direction.

Here, among the plurality of leads 12, leads connected to the bottom surfaces of the two MR elements 50A are referred to as lower leads and leads connected to the top surfaces of the two MR elements 50A are referred to as upper leads. The MR elements 50A are disposed, on the top surfaces of the lower leads, respectively near both ends in the direction parallel to the X direction. Each of the plurality of upper leads electrically connects two MR elements 50A that are disposed and adjacent to each other on the two lower leads adjacent at a distance from each other in the direction parallel to the X direction. Thus, the plurality of leads connect several MR elements 50A arranged in the direction parallel to the X direction.

The plurality of first element pairs may be disposed so that several first element pairs are aligned both in the X direction and in the Y direction. The first wiring 111 may further include a plurality of connection leads not shown. Here, a group of several MR elements 50A that are arranged in the direction parallel to the X direction is referred to as an element array. Each of the first to fourth resistor sections R11 to R14 of the first bridge circuit 110 includes a plurality of element arrays arranged along the direction parallel to the Y direction. As shown in FIG. 6, each of the plurality of connection leads connects two element arrays adjacent at a distance from each other in the direction parallel to the Y direction so that the shape of the first wiring 111 when viewed in the Z direction becomes a meandering shape in each of the first to fourth resistor sections R11 to R14.

Note that, in FIG. 6, for the sake of convenience, the dimension of the first yoke 40 in the direction parallel to the Y direction is drawn to be smaller than the dimension of the first wiring 111, that is, each of the plurality of leads 12 in the direction parallel to the Y direction. However, the foregoing dimension of the first yoke 40 may be greater than or equal to the above-described dimension of each of the plurality of leads 12. In addition, in FIG. 6, the first yoke 40 is drawn to extend only between one first MR element and one second MR element that are included in one first element pair. However, the first yoke 40 may extend to pass between a plurality of first MR elements and a plurality of second MR elements that are included in a plurality of first element pairs arranged in the direction parallel to the Y direction.

The second wiring 121 of the second bridge circuit 120 includes a plurality of leads 22 each formed of a conductive material. Each of the plurality of leads 22 electrically connects the first MR element and the second MR element of each of the plurality of second element pairs. Each of the plurality of leads 22 may include a part overlapping the first yoke 40 when viewed in the Z direction. More specifically, each of the plurality of leads 22 extends to pass above the first yoke 40 and connects the first MR element and the second MR element. In the example embodiment, in particular, each of the plurality of leads 22 connects the two MR elements 50B arranged in the direction parallel to the X direction. The dimension of the lead 22 in the direction parallel to the Y direction may be greater than that of the MR element 50B in the direction parallel to the Y direction.

Here, among the plurality of leads 22, leads connected to the bottom surfaces of the two MR elements 50B are referred to as lower leads and leads connected to the top surfaces of the two MR elements 50B are referred to as upper leads. The connection relationship between the plurality of MR elements 50B and the plurality of lower and upper leads is the same as the connection relationship between the plurality of MR elements 50A and the plurality of lower and upper leads.

The plurality of second element pairs may be disposed so that several second element pairs are aligned both in the X direction and in the Y direction. The second wiring 121 may further include a plurality of connection leads not shown. Each of the first to fourth resistor sections R21 to R24 of the second bridge circuit 120 includes a plurality of element arrays arranged along the direction parallel to the Y direction. Although not shown in the drawings, similarly to the first wiring 111, each of the plurality of connection leads connects two element arrays adjacent at a distance from each other in the direction parallel to the Y direction so that the shape of the second wiring 121 when viewed in the Z direction becomes a meandering shape in each of the first to fourth resistor sections R21 to R24.

Next, a configuration of the MR element 50 will be described with reference to FIG. 7. FIG. 7 is a perspective view showing the MR element 50. The MR element 50 is a spin-valve MR element. The MR element 50 includes a magnetization pinned layer 52, a direction of magnetization of which is fixed, a free layer 54, a direction of magnetization of which is variable depending on a direction of a magnetic field to be applied, and a gap layer 53 located between the magnetization pinned layer 52 and the free layer 54. The MR element 50 may be a tunneling magnetoresistive (TMR) element or a giant magnetoresistive (GMR) element. In the TMR element, the gap layer 53 is a tunnel barrier layer. In the GMR element, the gap layer 53 is a nonmagnetic conductive layer. The resistance of the MR element 50 changes with the angle that the direction of the magnetization of the free layer 54 forms with respect to the direction of the magnetization of the magnetization pinned layer 52. The resistance of the MR element 50 is at its minimum value when the foregoing angle is 0°, and at its maximum value when the foregoing angle is 180°.

The MR element 50 has a shape that is long in the direction parallel to the Y direction. The free layer 54 of the MR element 50 thus has a shape anisotropy such that the direction of the magnetization easy axis is parallel to the Y direction. In the state where there is no magnetic field to be applied, the direction of the magnetization of the free layer 54 is parallel to the Y direction. When there is a magnetic field component in the direction parallel to the X direction, the direction of the magnetization of the free layer 54 changes depending on the direction and the strength of the magnetic field component. The angle that the direction of the magnetization of the free layer 54 forms with respect to the direction of the magnetization of the magnetization pinned layer 52 thus changes depending on the direction and the strength of the magnetic field component received by the MR element 50. The MR element 50 thus has a resistance corresponding to the magnetic field component. Note that the direction of the magnetization easy axis can be set to the direction parallel to the Y direction by providing a magnet for applying a bias magnetic field to the free layer 54 regardless of the shape anisotropy, i.e., a bias magnetic field due to the shape anisotropy.

The MR element 50 further includes an antiferromagnetic layer 51. The antiferromagnetic layer 51, the magnetization pinned layer 52, the gap layer 53, and the free layer 54 are stacked in this order. The antiferromagnetic layer 51 is formed of an antiferromagnetic material, and is in exchange coupling with the magnetization pinned layer 52 to thereby fix the direction of the magnetization of the magnetization pinned layer 52. Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In the case where the magnetization pinned layer 52 is the self-pinned layer, the antiferromagnetic layer 51 may be omitted.

Note that the layers 51 to 54 of each MR element 50 may be stacked in the reverse order to that shown in FIG. 7.

Next, the direction of the magnetization of the magnetization pinned layer 52 will be described with reference to FIG. 3. The magnetization of the magnetization pinned layer 52 of each of the plurality of MR elements 50A in the first and third resistor sections R11 and R13 of the first bridge circuit 110 includes a component in a first magnetization direction. The magnetization of the magnetization pinned layer 52 of each of the plurality of MR elements 50A in the second and fourth resistor sections R12 and R14 of the first bridge circuit 110 includes a component in a second magnetization direction opposite the first magnetization direction. The magnetization of the magnetization pinned layer 52 of each of the plurality of MR elements 50B in the first and third resistor sections R21 and R23 of the second bridge circuit 120 includes a component in the first magnetization direction. The magnetization of the magnetization pinned layer 52 of each of the plurality of MR elements 50B in the second and fourth resistor sections R22 and R24 of the second bridge circuit 120 includes a component in the second magnetization direction. In the example embodiment, in particular, the first magnetization direction is the X direction, and the second magnetization direction is the −X direction. In FIG. 3, the plurality of arrows drawn respectively overlapping the resistor sections R11, R13, R21, and R23 indicate the first magnetization direction, and the plurality of arrows drawn respectively overlapping the resistor sections R12, R14, R22, and R24 indicate the second magnetization direction.

Note that, when the magnetization of the magnetization pinned layer 52 includes a component in a specific magnetization direction, the component in the specific magnetization direction may be the main component of the magnetization of the magnetization pinned layer 52. Alternatively, the magnetization of the magnetization pinned layer 52 does not have to include a component in the direction orthogonal to the specific magnetization direction. In the example embodiment, when the magnetization of the magnetization pinned layer 52 includes the component in the specific magnetization direction, the direction of the magnetization of the magnetization pinned layer 52 is the same or substantially the same as the specific magnetization direction.

Next, at least one detection signal generated by each of the first bridge circuit 110, the second bridge circuit 120, and the magnetic sensor 1 will be described in detail with reference to FIG. 3. The first bridge circuit 110 will be described first. The first bridge circuit 110 alone is configured to generate two detection signals corresponding to the magnetic field component in the direction parallel to the X direction. In other words, when the direction of the magnetic field component is in the X direction, the direction of the magnetization of the free layer 54 of the MR element 50A is inclined from the direction parallel to the Y direction toward the X direction. As a result, the resistance of each of the plurality of MR elements 50A of the first and third resistor sections R11 and R13 decreases and the resistance of the plurality of MR elements 50A of the second and fourth resistor sections R12 and R14 increases, compared to the state where there is no magnetic field component. As a result, the resistance of each of the first and third resistor sections R11 and R13 decreases and the resistance of each of the second and fourth resistor sections R12 and R14 increases.

When the direction of the magnetic field component is in the −X direction, the change in the resistance of each of the first to fourth resistor sections R11 to R14 is opposite to that in the foregoing case where the direction of the magnetic field component is in the X direction.

As described above, changes in the direction and the strength of the magnetic field component cause the resistances of the first to fourth resistor sections R11 to R14 to change such that the resistances of the first and third resistor sections R11 and R13 increase while the resistances of the second and fourth resistor sections R12 and R14 decrease, or such that the resistances of the first and third resistor sections R11 and R13 decrease while the resistances of the second and fourth resistor sections R12 and R14 increase. Thereby, the potential at each of the connection points P13 and P14 shown in FIG. 3 changes. The potentials at the connection points P13 and P14 correspond respectively to the two detection signals generated by the first bridge circuit 110.

Next, the second bridge circuit 120 will be described. The second bridge circuit 120 is alone configured to generate two detection signals corresponding to the magnetic field component in the direction parallel to the X direction, similarly to the first bridge circuit 110. The above-described description for the first bridge circuit 110 will be the description for the second bridge circuit 120, if the first bridge circuit 110, the plurality of MR elements 50A, the first to fourth resistor sections R11 to R14, and the connection points P13 and P14 are replaced respectively with the second bridge circuit 120, the plurality of MR elements 50B, the first to fourth resistor sections R21 to R24, and the connection points P23 and P24. The potentials at the connection points P23 and P24 correspond respectively to the two detection signals generated by the second bridge circuit 120.

Next, the at least one detection signal generated by the magnetic sensor 1 will be described. The connection point P13 of the first bridge circuit 110 and the connection point P23 of the second bridge circuit 120 are connected to the first signal output terminal E11. The connection point P14 of the first bridge circuit 110 and the connection point P24 of the second bridge circuit 120 are connected to the second signal output terminal E12. In the example embodiment, the potential at the connection point P13, the potential at the connection point P23, and the potential at the first signal output terminal E11 are equal to one another, and the potential at the connection point P14, the potential at the connection point P24, and the potential at the second signal output terminal E12 are equal to one another. The potential at each of the first and second signal output terminals E11 and E12 changes similarly to the potential at each of the connection points P13 and P14 in the first bridge circuit 110 alone or as the potential at each of the connection points P23 and P24 in the second bridge circuit 120 alone. The magnetic sensor 1 generates a signal corresponding to the potential at each of the first and second signal output terminals E11 and E12 or corresponding to a potential difference between the first and second signal output terminals E11 and E12, as the at least one detection signal. The at least one detection signal has a correspondence with the magnetic field component of the magnetic field to be detected in the X direction.

Next, other configurations of the magnetic sensor 1 according to the example embodiment will be briefly described. Although not shown in the drawings, the components of the magnetic sensor 1 excluding the substrate 5 are stacked on the substrate 5 along with a not-shown insulating layer disposed around the components of the magnetic sensor 1 excluding the substrate 5. The power supply terminal V1, the ground terminal G1, and the first and second signal output terminals E11 and E12 are formed in such a manner that they are exposed from the not-shown insulating layer.

Next, a manufacturing method for the magnetic sensor 1 according to the example embodiment will be briefly described. The manufacturing method for the magnetic sensor 1 includes a step of forming the first bridge circuit 110, a step of forming the plurality of first yokes 40, and a step of forming the second bridge circuit 120. The step of forming the first bridge circuit 110 and the step of forming the second bridge circuit 120 each include a step of forming the plurality of MR elements 50. The step of forming the first bridge circuit 110 further includes a step of forming the first wiring 111. The step of forming the second bridge circuit 120 further includes a step of forming the second wiring 121. The manufacturing method for the magnetic sensor 1 further includes a step of forming the insulating layer, not shown, a step of forming the connection electrodes 31 to 34, and a step of forming the power supply terminal V1, the ground terminal G1, the first signal output terminal E11, and the second signal output terminal E12.

In the step of forming the plurality of MR elements 50, initially, a plurality of initial MR elements to later become the plurality of MR elements 50 are formed. Each of the plurality of initial MR elements includes at least an initial magnetization pinned layer to later become the magnetization pinned layer 52, the free layer 54, and the gap layer 53. Each of the plurality of initial MR elements may further include the antiferromagnetic layer 51.

Next, the direction of the magnetization of the initial magnetization pinned layer is fixed in the specific direction using laser light and external magnetic fields in the foregoing specific direction. For example, the plurality of initial MR elements to later become the plurality of MR elements 50 of the resistor sections R11, R13, R21, and R23 are irradiated with laser light while an external magnetic field in the first magnetization direction (X direction) is applied thereto. In the case where the initial MR elements include the antiferromagnetic layers 51, the irradiation of the laser light is performed so that the temperature of the plurality of initial MR elements irradiated with the laser light becomes equal to or higher than a blocking temperature of the antiferromagnetic layers 51. The temperature of the plurality of initial MR elements can be adjusted, for example, by the intensity and the pulse width of the laser light. After the irradiation of the laser light, when the temperature of the plurality of initial MR elements becomes lower than the blocking temperature, the direction of the magnetization of the initial magnetization pinned layer is fixed in the first magnetization direction. This makes the initial magnetization pinned layers to be the magnetization pinned layers 52, and the plurality of initial MR elements to be the plurality of MR elements 50 of the resistor sections R11, R13, R21, and R23.

In a plurality of other initial MR elements to later become the plurality of MR elements 50 of the resistor sections R12, R14, R22, and R24, by setting the direction of the external magnetic field to the second magnetization direction (−X direction), the direction of the magnetization of the initial magnetization pinned layer of each of the plurality of other initial MR elements can be fixed in the second magnetization direction. The plurality of MR elements 50 of the resistor sections R12, R14, R22, and R24 are thus formed.

Note that the step of forming the plurality of MR elements 50 of the first bridge circuit 110 may be performed before the step of forming the plurality of first yokes 40. In addition, the step of forming the plurality of MR elements 50 of the second bridge circuit 120 may be performed after the step of forming the plurality of first yokes 40.

The operation and effect of the magnetic sensor 1 according to the example embodiment will now be described. In the example embodiment, the first bridge circuit 110 and the second bridge circuit 120 are disposed so that the plurality of first yokes 40 are interposed therebetween, and the first bridge circuit 110 and the second bridge circuit 120 are connected in parallel with each other. With such a configuration, according to the example embodiment, the occupancy area of the plurality of MR elements 50 can be increased while providing the plurality of first yokes 40. In the example embodiment, in particular, it is possible to double the occupancy area of the plurality of MR elements 50, compared to the case where only one bridge circuit is provided. Thus, according to the example embodiment, a noise included in the detection signal generated by the magnetic sensor 1 can be reduced.

In addition, according to the example embodiment, the occupancy area of the plurality of MR elements 50 can be increased without increasing the area of the planar shape (shape viewed in the Z direction) of the magnetic sensor 1. According to the example embodiment, it is thus possible to suppress the increase in the cost of the magnetic sensor 1.

When a comparison is made supposing that the number of the MR elements 50 is the same, according to the example embodiment, since the first bridge circuit 110 and the second bridge circuit 120 are connected in parallel with each other, the ratio of the resistances of the plurality of MR elements to the resistances in the bridge circuits becomes relatively large, compared to the configuration including only one bridge circuit, which enables decreased resistances of each of the first and second wirings 111 and 112. As a result, the sensitivity of the magnetic sensor 1 can be increased.

In the example embodiment, the MR element 50A has a shape that is long in the direction parallel to the Y direction. The plurality of leads 12 of the first wiring 111 each connect two MR elements 50A arranged in the direction parallel to the X direction, and include a part overlapping one of the plurality of first yokes 40 when viewed in the Z direction. According to the example embodiment, the dimension of each of the plurality of leads 12 in the direction parallel to the Y direction can be made substantially equal to the dimension of the MR element 50A in the longitudinal direction. According to the example embodiment, the resistance of the first wiring 111 can thus be reduced.

The foregoing description of the first wiring 111 also applies to the second wiring 121. According to the example embodiment, the resistance of the second wiring 121 can be reduced.

In addition, in the example embodiment, the first wiring 111 of the first bridge circuit 110 and the second wiring 121 of the second bridge circuit 120 are connected by the connection electrodes 31 to 34 each extending in the direction parallel to the Z direction. According to the example embodiment, the layout of the plurality of MR elements 50A and the plurality of leads 12 in the first bridge circuit 110 when viewed in the Z direction can be made the same as the layout of the plurality of MR elements 50B and the plurality of leads 22 in the second bridge circuit 120 when viewed in the Z direction. Furthermore, according to the example embodiment, the length of each of the connection electrodes 31 to 34 can be made shorter than the length of an electrode for connecting the first wiring 111 and the second wiring 121 in the case where the first bridge circuit 110 and the second bridge circuit 120 are disposed at positions different from each other in a direction orthogonal to the Z direction. According to the example embodiment, the resistances of the connection electrodes 31 to 34 can thus be reduced.

### Second Example Embodiment

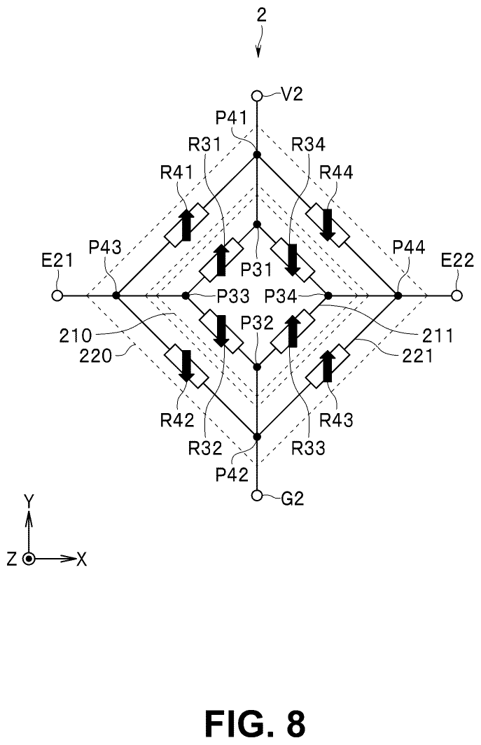

A second example embodiment of the disclosure will now be described. A schematic configuration of a magnetic sensor 2 according to the example embodiment will be described with reference to FIG. 8. FIG. 8 is a circuit diagram showing a circuit configuration of the magnetic sensor 2.

The magnetic sensor 2 includes a plurality of MR elements 50, and a first bridge circuit 210 and a second bridge circuit 220, each of which is constituted of the plurality of MR elements 50. The configuration of each of the plurality of MR elements 50 is the same as that in the first example embodiment. Each of the first bridge circuit 210 and the second bridge circuit 220 is configured to detect a magnetic field component of the magnetic field to be detected in the direction parallel to the Y direction and generate at least one detection signal corresponding to the strength of the magnetic field component. The first bridge circuit 210 and the second bridge circuit 220 are connected in parallel with each other.

The first bridge circuit 210 includes a first resistor section R31, a second resistor section R32, a third resistor section R33, and a fourth resistor section R34. The second bridge circuit 220 includes a first resistor section R41, a second resistor section R42, a third resistor section R43, and a fourth resistor section R44. Each of the resistor sections R31 to R34, and R41 to R44 is configured by several MR elements 50 of the plurality of MR elements 50 being electrically connected.

One end of each of the first and fourth resistor sections R31 and R34 is connected to a connection point P31. One end of each of the second and third resistor sections R32 and R33 is connected to a connection point P32. The other end of each of the first and second resistor sections R31 and R32 is connected to a connection point P33. The other end of each of the third and fourth resistor sections R33 and R34 is connected to a connection point P34.

One end of each of the first and fourth resistor sections R41 and R44 is connected to a connection point P41. One end of each of the second and third resistor sections R42 and R43 is connected to a connection point P42. The other end of each of the first and second resistor sections R41 and R42 is connected to a connection point P43. The other end of each of the third and fourth resistor sections R43 and R44 is connected to a connection point P44.

The magnetic sensor 2 further includes a power supply terminal V2, a ground terminal G2, a first signal output terminal E21, and a second signal output terminal E22. The connection points P31 and P41 are connected to the power supply terminal V2. The connection points P32 and P42 are connected to the ground terminal G2. The connection points P33 and P43 are connected to the first signal output terminal E21. The connection points P34 and P44 are connected to the second signal output terminal E22.

The first resistor sections R31 and R41 are disposed between the power supply terminal V2 and the first signal output terminal E21 in the circuit configuration. The first resistor sections R31 and R41 are connected in parallel with each other in the circuit configuration. The first resistor section R31 and the first resistor section R41 may be disposed so as to overlap each other when viewed in the Z direction. The first resistor section R41 may be disposed above the first resistor section R31.

The second resistor sections R32 and R42 are disposed between the ground terminal G2 and the first signal output terminal E21 in the circuit configuration. The second resistor sections R32 and R42 are connected in parallel with each other in the circuit configuration. The second resistor section R32 and the second resistor section R42 may be disposed so as to overlap each other when viewed in the Z direction. The second resistor section R42 may be disposed above the second resistor section R32.

The third resistor sections R33 and R43 are disposed between the ground terminal G2 and the second signal output terminal E22 in the circuit configuration. The third resistor sections R33 and R43 are connected in parallel with each other in the circuit configuration. The third resistor section R33 and the third resistor section R43 may be disposed so as to overlap each other when viewed in the Z direction. The third resistor section R43 may be disposed above the third resistor section R33.

The fourth resistor sections R34 and R44 are disposed between the power supply terminal V2 and the second signal output terminal E22 in the circuit configuration. The fourth resistor sections R34 and R44 are connected in parallel with each other in the circuit configuration. The fourth resistor section R34 and the fourth resistor section R44 are disposed so as to overlap each other when viewed in the Z direction. The fourth resistor section R44 may be disposed above the fourth resistor section R34.

Here, among the plurality of MR elements 50, the MR elements included in the first bridge circuit 210 are denoted by the reference numeral 50A, and the MR elements included in the second bridge circuit 220 are denoted by the reference numeral 50B. Note that any given MR element will be denoted by the reference numeral 50. The first bridge circuit 210 further includes a first wiring 211 that electrically connects the plurality of MR elements 50A. The second bridge circuit 220 further includes a second wiring 221 that electrically connects the plurality of MR elements 50B. The magnetic sensor 2 further includes first to fourth connection electrodes, not shown, that electrically connect the power supply terminal V2, the ground terminal G2, the first signal output terminal E21, the second signal output terminal E22, the first wiring 211, and the second wiring 221. The connection relationship between the terminals V2, G2, E21, E22 and wirings 211, 221 and the first to fourth connection electrodes is the same as the connection relationship between the terminals V1, G1, E11, E12 and wirings 111, 121 and the connection electrodes 31 to 34 in the first example embodiment. The shapes of the first to fourth connection electrodes are the same as those of the connection electrodes 31 to 34 in the first example embodiment.

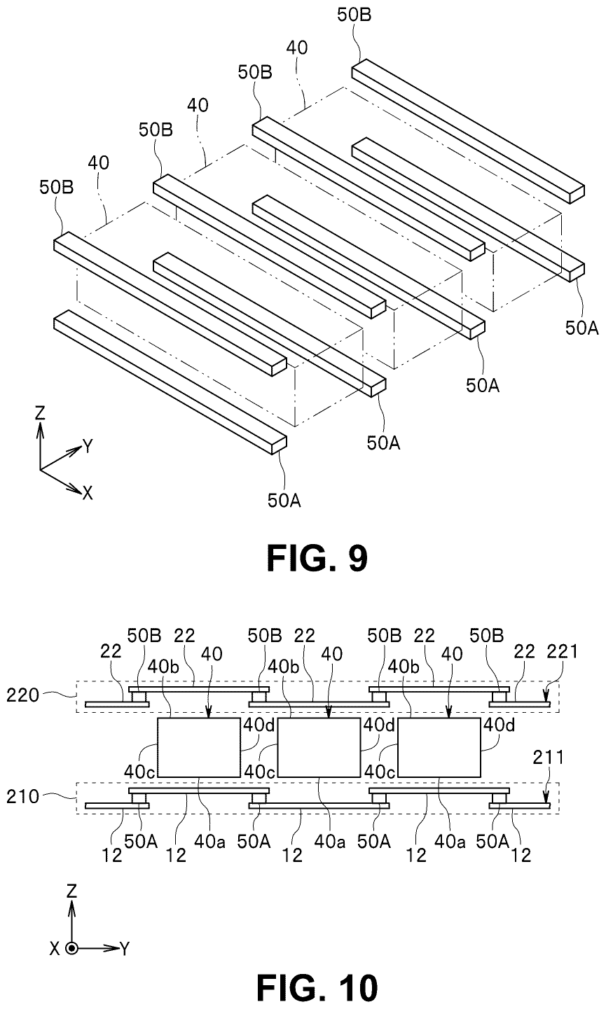

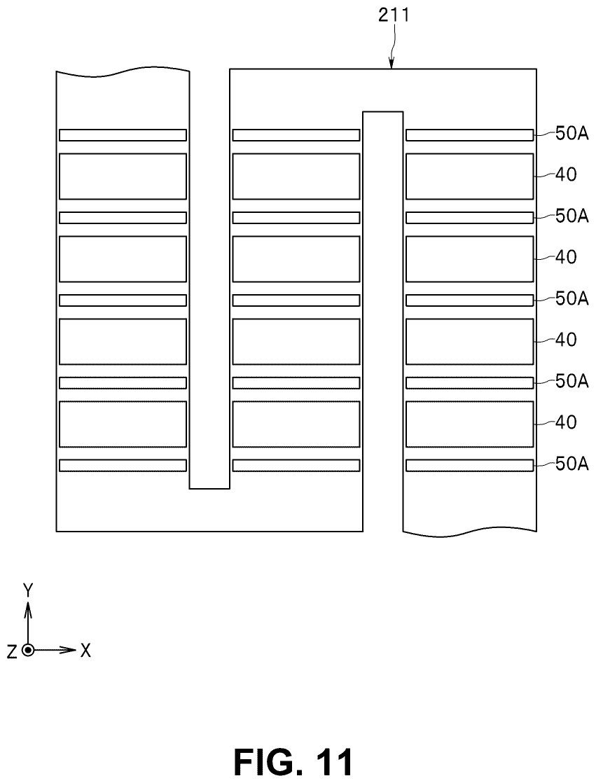

Hereinafter, configurations of the first and second bridge circuits 210 and 220 will be described in detail with reference to FIGS. 9 to 11. FIG. 9 is a perspective view showing a part of the magnetic sensor 2. FIG. 10 is a side view showing a part of the magnetic sensor 2. FIG. 11 is a plan view showing a part of the magnetic sensor 2.

The magnetic sensor 2 further includes a plurality of first yokes 40. In the example embodiment, the orientation of the plurality of first yokes 40 and the orientation of the MR elements 50 are different from those in the first example embodiment. When viewed in the Z direction, the orientation of the plurality of first yokes 40 and the orientation of the MR elements 50 are rotated by 90 degrees clockwise from the orientations described in the first example embodiment.

In the example embodiment, the plurality of first yokes 40 are configured to induce a magnetic field around the plurality of first yokes 40 and increase the strength of the magnetic field component of the magnetic field to be detected in the Y direction, the magnetic field to be detected being applied to the plurality of MR elements 50. Each of the plurality of first yokes 40 has a rectangular parallelepiped shape that is long in the direction parallel to the X direction. In each of the plurality of first yokes 40, a first end face 40c and a second end face 40d are located on opposite sides to each other in the direction parallel to the Y direction.

The first bridge circuit 210 and the second bridge circuit 220 are disposed so that the plurality of first yokes 40 are interposed therebetween. In the example embodiment, the first bridge circuit 210 is disposed below the plurality of first yokes 40. The second bridge circuit 220 is disposed above the plurality of first yokes 40. The relative positional relationship between the plurality of first yokes 40 and the plurality of MR elements 50 is the same as that in the first example embodiment.

The first wiring 211 of the first bridge circuit 210 includes a plurality of leads 12. The second wiring 221 of the second bridge circuit 220 includes a plurality of leads 22. The connection relationship between the plurality of leads 12 and the plurality of MR elements 50A and the connection relationship between the plurality of leads 22 and the plurality of MR elements 50B are the same as those in the first example embodiment. As shown in FIG. 11, the overall shape of the first wiring 211 may be a meandering shape. Similarly, the overall shape of the second wiring 221 may be a meandering shape. Note that, in the example embodiment, when viewed in the Z direction, the orientations of the plurality of leads 12 and 22 are rotated by 90 degrees clockwise from those described in the first example embodiment.

Next, the direction of the magnetization of the magnetization pinned layer 52 of the MR element 50 will be described with reference to FIG. 8. The magnetization of the magnetization pinned layer 52 of each of the plurality of MR elements 50A in the first and third resistor sections R31 and R33 of the first bridge circuit 210 includes a component in a first magnetization direction. The magnetization of the magnetization pinned layer 52 of each of the plurality of MR elements 50A in the second and fourth resistor sections R32 and R34 of the first bridge circuit 210 includes a component in a second magnetization direction opposite the first magnetization direction. The magnetization of the magnetization pinned layer 52 of each of the plurality of MR elements 50B in the first and third resistor sections R41 and R43 of the second bridge circuit 220 includes a component in the first magnetization direction. The magnetization of the magnetization pinned layer 52 of each of the plurality of MR elements 50B in the second and fourth resistor sections R42 and R44 of the second bridge circuit 220 includes a component in the second magnetization direction. In the example embodiment, in particular, the first magnetization direction is the Y direction, and the second magnetization direction is the −Y direction. In FIG. 8, the plurality of arrows drawn respectively overlapping the resistor sections R31, R33, R41, and R43 indicate the first magnetization direction, and the plurality of arrows drawn respectively overlapping the resistor sections R32, R34, R42, and R44 indicate the second magnetization direction.

Next, at least one detection signal generated by each of the first bridge circuit 210, the second bridge circuit 220, and the magnetic sensor 2 will be briefly described with reference to FIG. 8. The first bridge circuit 210 alone is configured to generate two detection signals corresponding to the magnetic field component in the direction parallel to the Y direction. Similarly to the first bridge circuit 110 in the first example embodiment, when the direction and the strength of the magnetic field component in the Y direction change, the potential at each of the connection points P33 and P34 shown in FIG. 8 changes. The potentials at the connection points P33 and P34 correspond respectively to the two detection signals generated by the first bridge circuit 210.

The second bridge circuit 220 alone is configured to generate two detection signals corresponding to the magnetic field component in the direction parallel to the Y direction, similarly to the first bridge circuit 210. Similarly to the second bridge circuit 120 in the first example embodiment, when the direction and the strength of the magnetic field component in the Y direction change, the potential at each of the connection points P43 and P44 shown in FIG. 8 changes. The potentials at the connection points P43 and P44 correspond respectively to the two detection signals generated by the second bridge circuit 220.

The potential at each of the first and second signal output terminals E21 and E22 of the magnetic sensor 2 changes similarly to the potential at each of the connection points P33 and P34 in the case of the first bridge circuit 210 alone or the potential at each of the connection points P43 and P44 in the case of the second bridge circuit 220 alone. The magnetic sensor 2 generates, as at least one detection signal, a signal corresponding to the potential at each of the first and second signal output terminals E21 and E22 or corresponding to a potential difference between the first and second signal output terminals E21 and E22. The at least one detection signal has a correspondence with the magnetic field component of the magnetic field to be detected in the Y direction.

The configuration, operation, and effects of the example embodiment are otherwise the same as those of the first example embodiment.

### Third Example Embodiment

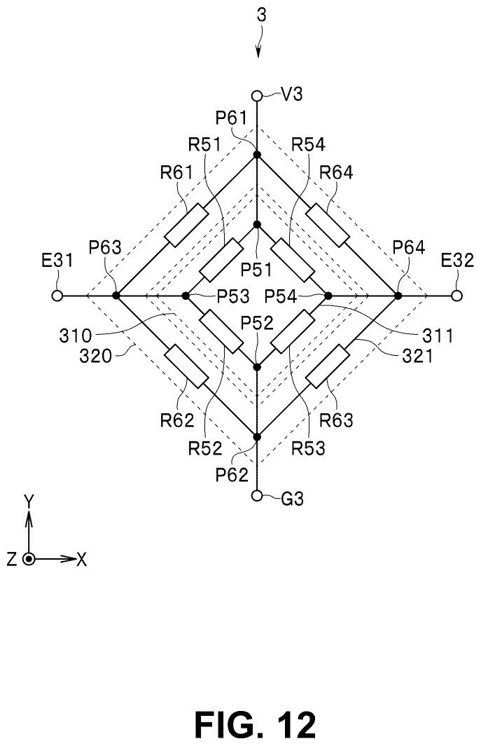

A third example embodiment of the disclosure will now be described. First, a schematic configuration of a magnetic sensor 3 according to the example embodiment will be described with reference to FIG. 12. FIG. 12 is a circuit diagram showing a circuit configuration of the magnetic sensor 3.

The magnetic sensor 3 includes a plurality of MR elements 50, and a first bridge circuit 310 and a second bridge circuit 320, each of which is constituted of the plurality of MR elements 50. The configuration of each of the plurality of MR elements 50 is the same as that in the first example embodiment. Each of the first bridge circuit 310 and the second bridge circuit 320 is configured to detect a magnetic field component of the magnetic field to be detected in the direction parallel to the Z direction and generate at least one detection signal corresponding to the strength of the magnetic field component. The first bridge circuit 310 and the second bridge circuit 320 are connected in parallel with each other.

The first bridge circuit 310 includes a first resistor section R51, a second resistor section R52, a third resistor section R53, and a fourth resistor section R54. The second bridge circuit 320 includes a first resistor section R61, a second resistor section R62, a third resistor section R63, and a fourth resistor section R64. Each of the resistor sections R51 to R54, and R61 to R64 is configured by several MR elements 50 of the plurality of MR elements 50 being electrically connected.

One end of each of the first and fourth resistor sections R51 and R54 is connected to a connection point P51. One end of each of the second and third resistor sections R52 and R53 is connected to a connection point P52. The other end of each of the first and second resistor sections R51 and R52 is connected to a connection point P53. The other end of each of the third and fourth resistor sections R53 and R54 is connected to a connection point P54.

One end of each of the first and fourth resistor sections R61 and R64 is connected to a connection point P61. One end of each of the second and third resistor sections R62 and R63 is connected to a connection point P62. The other end of each of the first and second resistor sections R61 and R62 is connected to a connection point P63. The other end of each of the third and fourth resistor sections R63 and R64 is connected to a connection point P64.

The magnetic sensor 3 further includes a power supply terminal V3, a ground terminal G3, a first signal output terminal E31, and a second signal output terminal E32. The connection points P51 and P61 are connected to the power supply terminal V3. The connection points P52 and P62 are connected to the ground terminal G3. The connection points P53 and P63 are connected to the first signal output terminal E31. The connection points P54 and P64 are connected to the second signal output terminal E32.

The first resistor sections R51 and R61 are disposed between the power supply terminal V3 and the first signal output terminal E31 in the circuit configuration. The first resistor sections R51 and R61 are connected in parallel with each other in the circuit configuration. The first resistor section R51 and the first resistor section R61 may be disposed so as to overlap each other when viewed in the Z direction. The first resistor section R61 may be disposed above the first resistor section R51.

The second resistor sections R52 and R62 are disposed between the ground terminal G3 and the first signal output terminal E31 in the circuit configuration. Further, the second resistor sections R52 and R62 are connected in parallel with each other in the circuit configuration. Furthermore, the second resistor section R52 and the second resistor section R62 may be disposed so as to overlap each other when viewed in the Z direction. The second resistor section R62 may be disposed above the second resistor section R52.

The third resistor sections R53 and R63 are disposed between the ground terminal G3 and the second signal output terminal E32 in the circuit configuration. The third resistor sections R53 and R63 are connected in parallel with each other in the circuit configuration. The third resistor sections R53 and R63 may be disposed so as to overlap each other when viewed in the Z direction. The third resistor section R63 may be disposed above the third resistor section R53.

The fourth resistor sections R54 and R64 are disposed between the power supply terminal V3 and the second signal output terminal E32 in the circuit configuration. The fourth resistor sections R54 and R64 are connected in parallel with each other in the circuit configuration. The fourth resistor section R54 and the fourth resistor section R64 are disposed so as to overlap each other when viewed in the Z direction. The fourth resistor section R64 may be disposed above the fourth resistor section R54.

Here, among the plurality of MR elements 50, the MR elements included in the first bridge circuit 310 are denoted by the reference numeral 50A, and the MR elements included in the second bridge circuit 320 are denoted by the reference numeral 50B. Note that any given MR element will be denoted by the reference numeral 50. The first bridge circuit 310 further includes a first wiring 311 that electrically connects the plurality of MR elements 50A. The second bridge circuit 320 further includes a second wiring 321 that electrically connects the plurality of MR elements 50B. The magnetic sensor 3 further includes a first to fourth connection electrodes, not shown, that electrically connect the power supply terminal V3, the ground terminal G3, the first signal output terminal E31, the second signal output terminal E32, the first wiring 311, and the second wiring 321. The connection relationship between the terminals V3, G3, E31, E32 and wirings 311, 321 and the first to fourth connection electrodes is the same as the connection relationship between the terminals V1, G1, E11, E12 and wirings 111, 121 and the connection electrodes 31 to 34 in the first example embodiment. The shapes of the first to fourth connection electrodes are the same as those of the connection electrodes 31 to 34 in the first example embodiment.

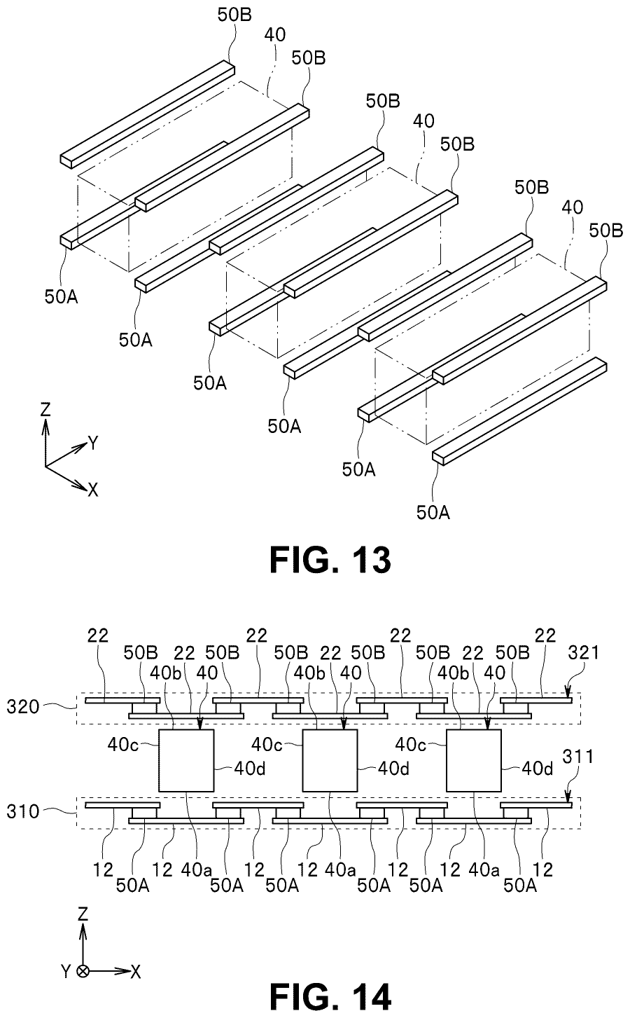

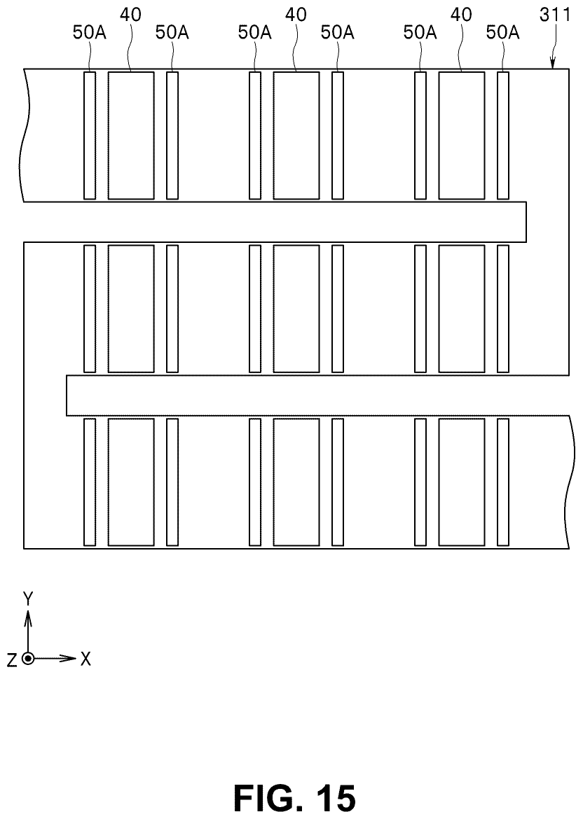

Next, configurations of the first and second bridge circuits 310 and 320 will be described in detail with reference to FIGS. 13 to 15. FIG. 13 is a perspective view showing a part of the magnetic sensor 3. FIG. 14 is a side view showing a part of the magnetic sensor 3. FIG. 15 is a plan view showing a part of the magnetic sensor 3.

The magnetic sensor 3 further includes a plurality of first yokes 40. In the example embodiment, the plurality of first yokes 40 are configured to induce an input magnetic field including an input magnetic field component in the direction parallel to the Z direction to generate an output magnetic field. The output magnetic field is a part of the magnetic field induced by the plurality of first yokes 40 and includes an output magnetic field component which is an output magnetic field component in the direction parallel to the X direction and which changes depending on the input magnetic field component.

Note that, in the application, the “input magnetic field component” is a magnetic field component at a position away from the first yokes 40. If it is supposed that no first yoke 40 exists, the “input magnetic field component” is substantially the same as the magnetic field component near the position for disposing the first yokes 40. In addition, in the application, the “output magnetic field component” is a magnetic field component at the place which is near the first yokes 40 and where the MR elements 50 are present. The “output magnetic field component” changes, due to the first yokes 40, from the magnetic field component (input magnetic field component) in the case where it is supposed that no first yoke 40 exists.

Each of the plurality of first yokes 40 has a rectangular parallelepiped shape that is long in the direction parallel to the Y direction. In addition, in each of the plurality of first yokes 40, the first end face 40c and the second end face 40d are located on opposite sides to each other in the direction parallel to the X direction.

The first bridge circuit 310 and the second bridge circuit 320 are disposed so that the plurality of first yokes 40 are interposed therebetween. In the example embodiment, the first bridge circuit 310 is disposed below the plurality of first yokes 40. The second bridge circuit 320 is disposed above the plurality of first yokes 40. The positional relationship between the plurality of first yokes 40 and the plurality of MR elements 50 is different from that in the first example embodiment in the point to be described below. Two MR elements 50A and two MR elements 50B are disposed between two first yokes 40 adjacent at a distance from each other in the direction parallel to the X direction, when viewed in the Z direction. As described in the first example embodiment, the plurality of element pairs each include the first MR element disposed near the first end face 40c of the one first yoke 40 and the second MR element disposed near the second end face 40d of the same one first yoke 40. The MR element 50A of the two MR elements 50A, which is disposed near the first yoke 40 located on the −X direction side of the two MR elements 50A, corresponds to the second MR element. The MR element 50A of the two MR elements 50A, which is disposed near the first yoke 40 located on the X direction side of the two MR elements 50A, corresponds to the first MR element.

Similarly, the MR element 50B of the two MR elements 50B, which is disposed near the first yoke 40 located on the −X direction side of the two MR elements 50B, corresponds to the second MR element. The MR element 50B of the two MR elements 50B, which is disposed near the first yoke 40 located on the X direction side of the two MR elements 50B, corresponds to the first MR element.

The positional relationship between the plurality of first yokes 40 and the plurality of MR elements 50 is the same as that in the first example embodiment in the points other than the above-described point.

The first wiring 311 of the first bridge circuit 310 includes a plurality of leads 12. In the example embodiment, each of the plurality of leads 12 connects the first MR element and the second MR element of one element pair (one first element pair), or connects the first MR element of one of two element pairs (two first element pairs) and the second MR element of the other of the two element pairs. The first MR element and the second MR element of the one element pair may be connected by the lower lead or by the upper lead. The connection relationship between the plurality of leads 12 and the plurality of MR elements 50A are the same as that in the first example embodiment in the points other than the above-described point.

The second wiring 321 of the second bridge circuit 320 includes a plurality of leads 22. In the example embodiment, each of the plurality of leads 22 connects the first MR element and the second MR element of one element pair (one second element pair), or connects the first MR element of one of two element pairs (two second element pairs) and the second MR element of the other of the two element pairs. The first MR element and the second MR element of the one element pair may be connected by the lower lead or by the upper lead. The connection relationship between the plurality of leads 22 and the plurality of MR elements 50B are the same as that in the first example embodiment in the points other than the above-described point.

As shown in FIG. 15, the overall shape of the first wiring 311 may be a meandering shape. Similarly, the overall shape of the second wiring 321 may be a meandering shape.

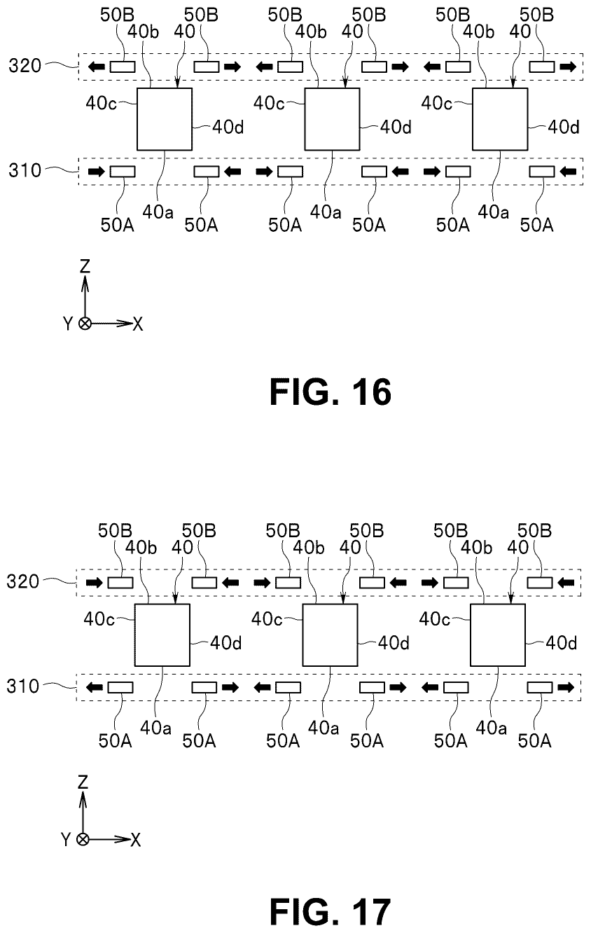

Next, the direction of the magnetization of the magnetization pinned layer 52 of the MR element 50 will be described. First, with reference to FIG. 16, the direction of the magnetization of the magnetization pinned layer 52 in each of the first and third resistor sections R51 and R53 of the first bridge circuit 310 and the direction of the magnetization of the magnetization pinned layer 52 in each of the first and third resistor sections R61 and R63 of the second bridge circuit 320 will be described.

In the first and third resistor sections R51 and R53 of the first bridge circuit 310, the magnetization of the magnetization pinned layer 52 of the MR element 50A (first MR element), which is disposed near the first end face 40c of each of the plurality of first yokes 40, of the plurality of MR elements 50A, includes a component in the first magnetization direction. In addition, the magnetization of the magnetization pinned layer 52 of the MR element 50A (second MR element), which is disposed near the second end face 40d of each of the plurality of first yokes 40, of the plurality of MR elements 50A, includes a component in the second magnetization direction opposite the first magnetization direction.

In the first and third resistor sections R61 and R63 of the second bridge circuit 320, the magnetization of the magnetization pinned layer 52 of the MR element 50B (first MR element), which is disposed near the first end face 40c of each of the plurality of first yokes 40, of the plurality of MR elements 50B, includes a component in the second magnetization direction. In addition, the magnetization of the magnetization pinned layer 52 of the MR element 50B (second MR element), which is disposed near the second end face 40d of each of the plurality of first yokes 40, of the plurality of MR elements 50B, includes a component in the first magnetization direction.

In the example embodiment, in particular, the first magnetization direction is the X direction, and the second magnetization direction is the −X direction.

In FIG. 16, the plurality of arrows represent the first magnetization direction and the second magnetization direction. For example, the arrow drawn near the MR element 50A disposed near the first end face 40c indicates that the magnetization of the magnetization pinned layer 52 of this MR element 50A includes the component in the first magnetization direction. In addition, the arrow drawn near the MR element 50A disposed near the second end face 40d indicates that the magnetization of the magnetization pinned layer 52 of this MR element 50A includes the component in the second magnetization direction. Note that, also in the drawings to be used in the description below, which are similar to FIG. 16, the first magnetization direction and the second magnetization direction are illustrated in the same manner as in FIG. 16.

Next, with reference to FIG. 17, the direction of the magnetization of the magnetization pinned layer 52 in each of the second and fourth resistor section R52 and R54 of the first bridge circuit 310 and the direction of the magnetization of the magnetization pinned layer 52 in each of the second and fourth resistor sections R62 and R64 of the second bridge circuit 320 will be described.

In the second and fourth resistor sections R52 and R54 of the first bridge circuit 310, the magnetization of the magnetization pinned layer 52 of the MR element 50A (first MR element), which is disposed near the first end face 40c of each of the plurality of first yokes 40, of the plurality of MR elements 50A, includes a component in the second magnetization direction (−X direction). In addition, the magnetization of the magnetization pinned layer 52 of the MR element 50A (second MR element), which is disposed near the second end face 40d of each of the plurality of first yokes 40, of the plurality of MR elements 50A, includes a component in the first magnetization direction (X direction).

In the second and fourth resistor sections R62 and R64 of the second bridge circuit 320, the magnetization of the magnetization pinned layer 52 of the MR element 50B (first MR element), which is disposed near the first end face 40c of each of the plurality of first yokes 40, of the plurality of MR elements 50B, includes a component in the first magnetization direction (X direction). In addition, the magnetization of the magnetization pinned layer 52 of the MR element 50B (second MR element), which is disposed near the second end face 40d of each of the plurality of first yokes 40, of the plurality of MR elements 50B, includes a component in the second magnetization direction (−X direction).

Here, focus is placed on one first yoke 40 (specific yoke). As shown in FIG. 16 and FIG. 17, the magnetization of the magnetization pinned layer 52 of one of two first MR elements (MR element 50A and MR element 50B) that are disposed near the first end face 40c and the magnetization of the magnetization pinned layer 52 of the other of the two first MR elements include the components in the directions opposite each other. Note that the two first MR elements may be disposed so as to overlap each other when viewed in the Z direction.

Similarly, the magnetization of the magnetization pinned layer 52 of one of two second MR elements (MR element 50A and MR element 50B) that are disposed near the second end face 40d and the magnetization of the magnetization pinned layer 52 of the other of the two second MR elements include the components in the directions opposite each other. Note that the two second MR elements may be disposed so as to overlap each other when viewed in the Z direction.

Next, at least one detection signal generated by each of the first bridge circuit 310, the second bridge circuit 320, and the magnetic sensor 3 will be described in detail, with reference to FIG. 12, FIG. 16, and FIG. 17. The first bridge circuit 310 will be described first. The first bridge circuit 310 alone is configured to generate two detection signals corresponding to the magnetic field component in the direction parallel to the Z direction. In other words, in the state where there is no input magnetic field component and, as a result, there is no output magnetic field component, the direction of the magnetization of the free layer 54 of each of the plurality of MR elements 50A is parallel to the Y direction.

In the state where the input magnetic field component in the Z direction exists, the direction of the output magnetic field component that the MR element 50A (first MR element) disposed near the first end face 40c of each of the plurality of first yokes 40 receives is in the X direction, and the direction of the output magnetic field component that the MR element 50A (second MR element) disposed near the second end face 40d of each of the plurality of first yokes 40 receives is in the −X direction. In this case, the direction of the magnetization of the free layer 54 of the first MR element is inclined from the direction parallel to the Y direction to the X direction, and the direction of the magnetization of the free layer 54 of the second MR element is inclined from the direction parallel to the Y direction to the −X direction. As a result, the resistance of each of the plurality of MR elements 50A constituting the first and third resistor sections R51 and R53 decreases, and the resistance of each of the first and third resistor sections R51 and R53 also decreases compared to a state where there exists no output magnetic field component. Meanwhile, the resistance of each of the plurality of MR elements 50A constituting the second and fourth resistor sections R52 and R54 increases, and the resistance of each of the second and fourth resistor sections R52 and R54 also increases compared to the state where there exists no output magnetic field component.

When the direction of the input magnetic field component is in the −Z direction, the directions of the output magnetic field components and the changes in the resistances of the respective first to fourth resistor sections R51 to R54 are opposite to those in the foregoing case where the direction of the input magnetic field component is in the Z direction.

The amount of change in the resistance of each of the MR elements 50A depends on the strength of the output magnetic field component that each of the MR elements 50A receives. As the strength of the output magnetic field component increases, the resistance of each of the MR elements 50A changes so that the amount of increase or the amount of decrease increases. As the strength of the output magnetic field component decreases, the resistance of each of the MR elements 50A changes so that the amount of increase or the amount of decrease decreases. The strength of the output magnetic field component depends on the strength of the input magnetic field component.

As described above, changes in the strength of the input magnetic field component cause the resistances of the first to fourth resistor sections R51 to R54 to change such that the resistances of the respective first and third resistor sections R51 and R53 increase while the resistances of the respective second and fourth resistor sections R52 and R54 decrease, or such that the resistances of the respective first and third resistor sections R51 and R53 decrease while the resistances of the respective second and fourth resistor sections R52 and R54 increase. As a result, the potential at each of the connection points P53 and P54 shown in FIG. 12 changes. The potentials at the connection points P53 and P54 correspond respectively to the two detection signals generated by the first bridge circuit 310.

Next, the second bridge circuit 320 will be described. The second bridge circuit 320 alone is configured to generate two detection signals corresponding to the magnetic field component in the direction parallel to the Z direction, similarly to the first bridge circuit 310. The foregoing description of the first bridge circuit 310 is basically applied also to the second bridge circuit 320. However, in the second bridge circuit 320, in the state where the input magnetic field component in the Z direction exists, the direction of the output magnetic field component that the MR element 50B (first MR element) disposed near the first end face 40c of each of the plurality of first yokes 40 receives is in the −X direction, and the direction of the output magnetic field component that the MR element 50B (second MR element) disposed near the second end face 40d of each of the plurality of first yokes 40 receives is in the X direction.

The aspect of the changes in the resistances of the respective first to fourth resistor sections R61 to R64 in the case where the direction of the input magnetic field component is in the Z direction is the same as that of the changes in the resistances of the respective first to fourth resistor sections R51 to R54 in the case where the direction of the input magnetic field component is in the Z direction. In addition, the aspect of the changes in the resistances of the respective first to fourth resistor sections R61 to R64 in the case where the direction of the input magnetic field component is in the −Z direction is the same as that of the changes in the resistances of the respective first to fourth resistor sections R51 to R54 in the case where the direction of the input magnetic field component is in the −Z direction.

Next, at least one detection signal generated by the magnetic sensor 3 will be described. The connection point P53 of the first bridge circuit 310 and the connection point P63 of the second bridge circuit 320 are connected to the first signal output terminal E31. The connection point P54 of the first bridge circuit 310 and the connection point P64 of the second bridge circuit 320 are connected to the second signal output terminal E32. In the example embodiment, the potential at the connection point P53, the potential at the connection point P63, and the potential at the first signal output terminal E31 are equal to one another, and the potential at the connection point P54, the potential at the connection point P64, and the potential at the second signal output terminal E32 are equal to one another. The potential at each of the first and second signal output terminals E31 and E32 changes in a similar manner as the potential at each of the connection points P53 and P54 in the case of the first bridge circuit 310 alone or the potential at each of the connection points P63 and P64 in the case of the second bridge circuit 320 alone. The magnetic sensor 3 generates, as at least one detection signal, a signal corresponding to the potential at each of the first and second signal output terminals E31 and E32 or corresponding to a potential difference between the first and second signal output terminals E31 and E32. The at least one detection signal has a correspondence with the magnetic field component of the magnetic field to be detected in the Z direction.

Next, a first example and a second example of a manufacturing method for the magnetic sensor 3 according to the example embodiment will be briefly described. The first example will be described first. The contents of the first example are the same as the contents of the manufacturing method for the magnetic sensor 1 according to the first example embodiment. In the first example, in particular, in the step of forming a plurality of MR elements 50, after forming a plurality of initial MR elements to later become the plurality of MR elements 50, the direction of the magnetization of the initial magnetization pinned layer is fixed in the above-described specific direction using laser light and an external magnetic field in the specific direction.

Next, the second example will be described. In the second example, the step of fixing the direction of the magnetization of the initial magnetization pinned layer is different from that in the first example. In other words, in the second example, in the step of forming the plurality of MR elements 50, after forming the plurality of initial MR elements to later become the plurality of MR elements 50, annealing treatment of heating the plurality of initial MR elements at a specific temperature is performed while applying an external magnetic field in one direction parallel to the Z direction so that the direction of the magnetization of the initial magnetization pinned layer is fixed. For example, in the plurality of initial MR elements that later become the plurality of MR elements 50 of the resistor sections R51, R53, R61, and R63, the annealing treatment is performed while applying an external magnetic field in the Z direction to the plurality of initial MR elements. Thereby, the plurality of initial MR elements become the plurality of MR elements 50 of the resistor sections R51, R53, R61, and R63.

In a plurality of other initial MR elements to later become the plurality of MR elements 50 of the resistor sections R52, R54, R62, and R64, by setting the direction of the external magnetic field in the −Z direction, the other plurality of MR elements become the plurality of MR elements 50 of the resistor sections R52, R54, R62, and R64.

The configuration, operation, and effects of the example embodiment are otherwise the same as those of the first example embodiment.

### Fourth Example Embodiment

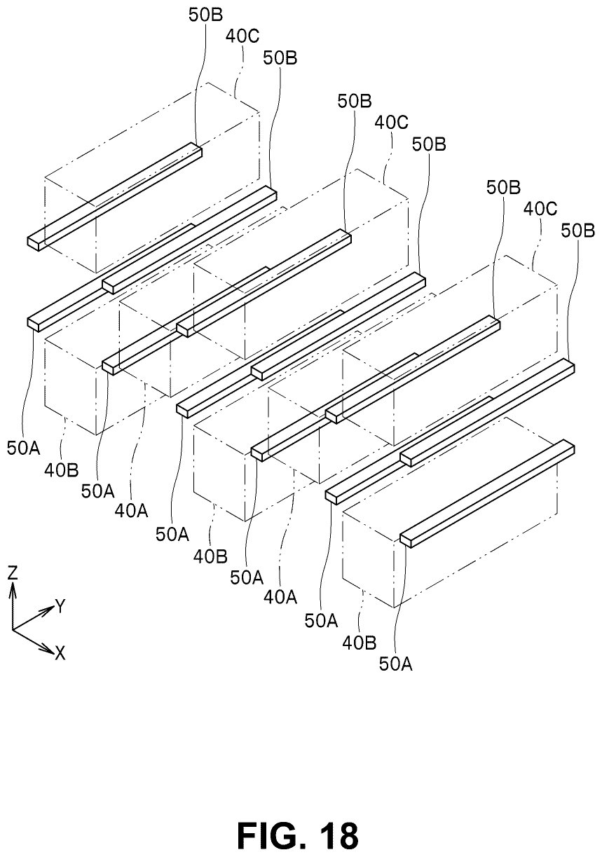

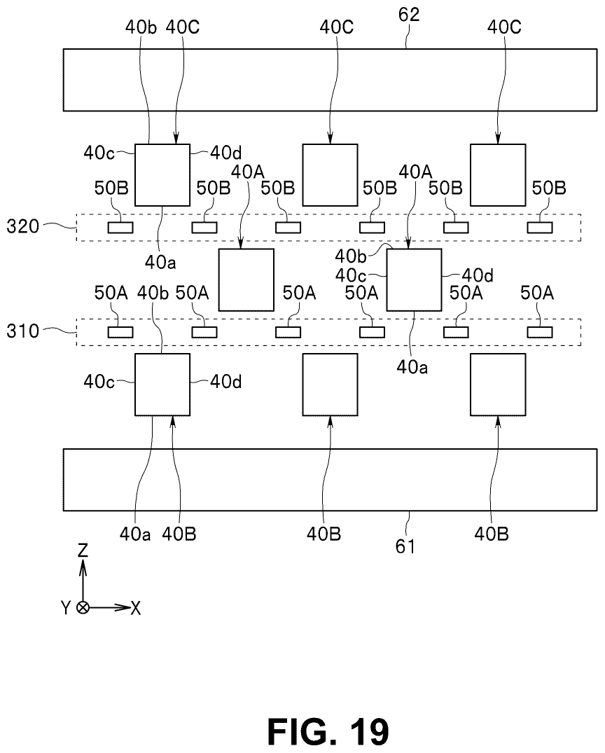

A fourth example embodiment of the disclosure will now be described with reference to FIGS. 18 and 19. FIG. 18 is a perspective view showing a part of a magnetic sensor according to the example embodiment. FIG. 19 is a side view showing a part of the magnetic sensor according to the example embodiment.

Hereinafter, a plurality of first yokes will be denoted by the reference numeral 40A. In the example embodiment, the plurality of yokes of the magnetic sensor 3 may include a plurality of second yokes 40B and a plurality of third yokes 40C that are disposed so that the plurality of first yokes 40A are interposed therebetween when viewed in one direction parallel to the Y direction, in addition to the plurality of first yokes 40A. The plurality of second yokes 40B may be disposed at the same position in the direction parallel to the Z direction. The plurality of third yokes 40C may be disposed at the same position in the direction parallel to the Z direction.

The plurality of second yokes 40B are disposed below the plurality of first yokes 40A. The plurality of third yokes 40C are disposed above the plurality of first yokes 40A. The first bridge circuit 310 may be disposed between the plurality of first yokes 40A and the plurality of second yokes 40B. The second bridge circuit 320 may be disposed between the plurality of first yokes 40A and the plurality of third yokes 40C.

Each of the plurality of second yokes 40B and the plurality of third yokes 40C is configured to receive an input magnetic field including an input magnetic field component in the direction parallel to the Z direction and generate an output magnetic field, similarly to the plurality of first yokes 40A. Each of the plurality of second yokes 40B and the plurality of third yokes 40C has a rectangular parallelepiped shape that is long in the direction parallel to the Y direction. Each of the plurality of second yokes 40B and the plurality of third yokes 40C has a bottom surface and a top surface that are located on opposite sides to each other in the direction parallel to the Z direction, and a first end face and a second end face that are located on opposite sides to each other in the direction parallel to the X direction. In the description below, the bottom surface, the top surface, the first end face, and the second end face of each of the plurality of second yokes 40B and the plurality of third yokes 40C are also denoted by using the reference numerals 40a, 40b, 40c, and 40d, respectively.

Each of the plurality of second yokes 40B is disposed between two first yokes 40A adjacent at a distance from each other in the direction parallel to the X direction when viewed in the Z direction. In addition, between the first yoke 40A and the second yoke 40B that are adjacent at a distance from each other in the direction parallel to the X direction when viewed in the Z direction, one MR element 50A of the first bridge circuit 310 is disposed.

Each of the plurality of third yokes 40C is disposed between two first yokes 40A adjacent at a distance from each other in the direction parallel to the X direction when viewed in the Z direction. In addition, between the first yoke 40A and the third yoke 40C that are adjacent at a distance from each other in the direction parallel to the X direction when viewed in the Z direction, one MR element 50B of the second bridge circuit 320 is disposed.

When viewed in the Z direction, each of the plurality of third yokes 40C may overlap each of the plurality of second yokes 40B.

The magnetic sensor 3 may further include at least one shield formed of a soft magnetic material and disposed so as to overlap the first and second bridge circuits 310 and 320 when viewed in the Z direction. In the example embodiment, the magnetic sensor 3 includes two shields 61 and 62 as the at least one shield. The shield 61 is disposed below the plurality of second yokes 40B. The shield 62 is disposed above the plurality of third yokes 40C. The dimension of each of the shields 61 and 62 in the Z direction may be smaller than the dimension of each of the shields 61 and 62 in the X direction and the dimension of each of the shields 61 and 62 in the Y direction.

The configuration, operation, and effects of the example embodiment are otherwise the same as those of the third example embodiment.

### Fifth Example Embodiment

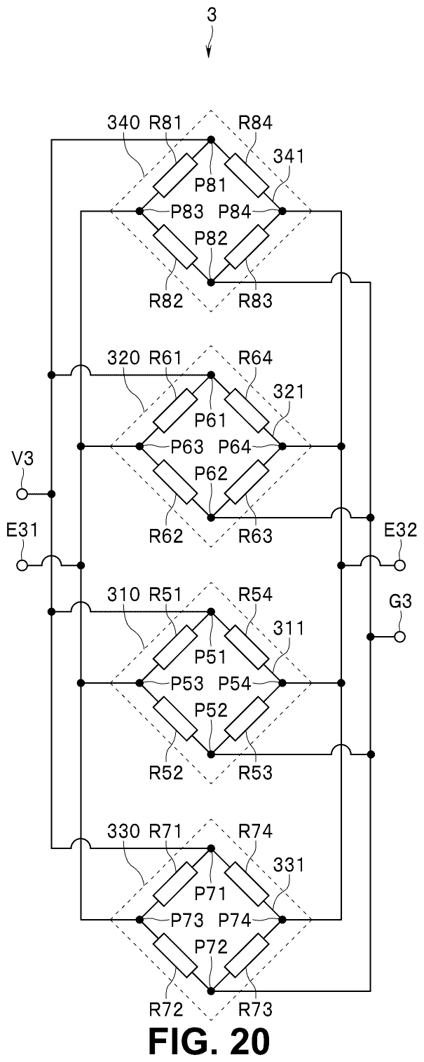

A fifth example embodiment of the disclosure will now be described. First, a schematic configuration of a magnetic sensor 3 according to the example embodiment will be described with reference to FIG. 20. FIG. 20 is a circuit diagram showing a circuit configuration of the magnetic sensor 3.

The magnetic sensor 3 according to the example embodiment may include a third bridge circuit 330 and a fourth bridge circuit 340 each configured by a plurality of MR elements 50, in addition to the first and second bridge circuits 310 and 320 in the fourth example embodiment. Each of the third bridge circuit 330 and the fourth bridge circuit 340 is configured to detect a magnetic field component of the magnetic field to be detected in the direction parallel to the Z direction and generate at least one detection signal corresponding to the strength of the magnetic field component. The first to fourth bridge circuits 310, 320, 330, and 340 are connected in parallel with each other.

The third bridge circuit 330 includes a first resistor section R71, a second resistor section R72, a third resistor section R73, and a fourth resistor section R74. The fourth bridge circuit 340 includes a first resistor section R81, a second resistor section R82, a third resistor section R83, and a fourth resistor section R84. Each of the resistor sections R71 to R74 and R81 to R84 is configured by several MR elements 50 of the plurality of MR elements 50 being electrically connected.

One end of each of the first and fourth resistor sections R71 and R74 is connected to a connection point P71. One end of each of the second and third resistor sections R72 and R73 is connected to a connection point P72. The other end of each of the first and second resistor sections R71 and R72 is connected to a connection point P73. The other end of each of the third and fourth resistor sections R73 and R74 is connected to a connection point P74.

One end of each of the first and fourth resistor sections R81 and R84 is connected to a connection point P81. One end of each of the second and third resistor sections R82 and R83 is connected to a connection point P82. The other end of each of the first and second resistor sections R81 and R82 is connected to a connection point P83. The other end of each of the third and fourth resistor sections R83 and R84 is connected to a connection point P84.

The connection points P71 and P81 are connected to the power supply terminal V3, together with the connection points P51 and P61. The connection points P72 and P82 are connected to the ground terminal G3, together with the connection points P52 and P62. The connection points P73 and P83 are connected to the first signal output terminal E31, together with the connection points P53 and P63. The connection points P74 and P84 are connected to the second signal output terminal E32, together with the connection points P54 and P64.

The first resistor sections R51, R61, R71, and R81 are disposed between the power supply terminal V3 and the first signal output terminal E31 in the circuit configuration. The first resistor sections R51, R61, R71, and R81 are connected in parallel with one another in the circuit configuration. The first resistor sections R51, R61, R71, and R81 may be disposed so as to overlap one another when viewed in the Z direction. The first resistor section R71 may be disposed below the first resistor section R51. The first resistor section R81 may be disposed above the first resistor section R61.

The second resistor sections R52, R62, R72, and R82 are disposed between the ground terminal G3 and the first signal output terminal E31 in the circuit configuration. The second resistor sections R52, R62, R72, and R82 are connected in parallel with one another in the circuit configuration. The second resistor sections R52, R62, R72, and R82 may be disposed so as to overlap one another when viewed in the Z direction. The second resistor section R72 may be disposed below the second resistor section R52. The second resistor section R82 may be disposed above the second resistor section R62.

The third resistor sections R53, R63, R73, and R83 are disposed between the ground terminal G3 and the second signal output terminal E32 in the circuit configuration. The third resistor sections R53, R63, R73, and R83 are connected in parallel with one another in the circuit configuration. The third resistor sections R53, R63, R73, and R83 may be disposed so as to overlap one another when viewed in the Z direction. The third resistor section R73 may be disposed below the third resistor section R53. The third resistor section R83 may be disposed above the third resistor section R63.

The fourth resistor sections R54, R64, R74, and R84 are disposed between the power supply terminal V3 and the second signal output terminal E32 in the circuit configuration. The fourth resistor sections R54, R64, R74, and R84 are connected in parallel with one another in the circuit configuration. The fourth resistor sections R54, R64, R74, and R84 may be disposed so as to overlap one another when viewed in the Z direction. The fourth resistor section R74 may be disposed below the fourth resistor section R54. The fourth resistor section R84 may be disposed above the fourth resistor section R64.

Here, among the plurality of MR elements 50, the MR elements included in the third bridge circuit 330 are denoted by the reference numeral 50C, and the MR elements included in the fourth bridge circuit 340 are denoted by the reference numeral 50D. The third bridge circuit 330 further includes a third wiring 331 that electrically connects the plurality of MR elements 50C. The fourth bridge circuit 340 further includes a fourth wiring 341 that electrically connects the plurality of MR elements 50D. First to fourth connection electrodes, not shown, of the magnetic sensor 3 electrically connect the power supply terminal V3, the ground terminal G3, the first signal output terminal E31, the second signal output terminal E32, the first wiring 311, the second wiring 321, the third wiring 331, and the fourth wiring 341.

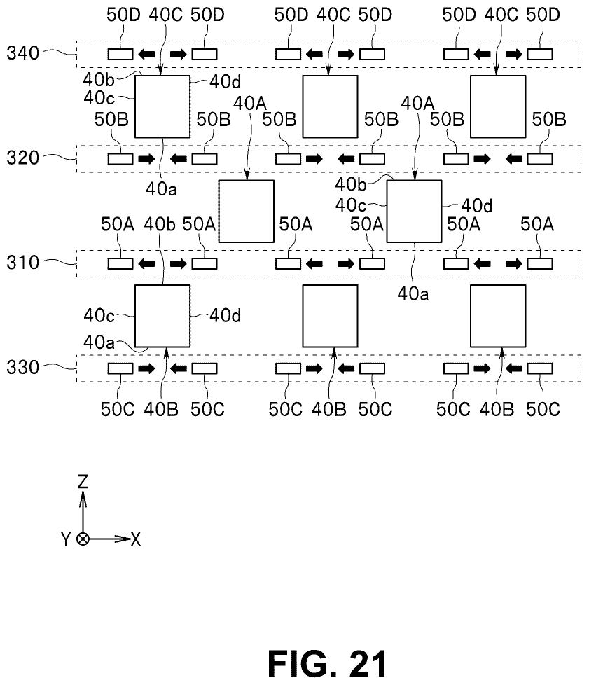

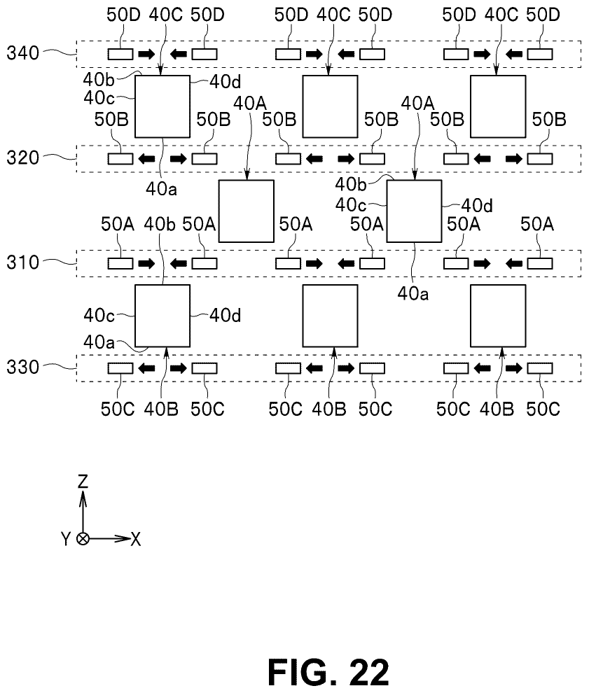

Next, configurations of the third and fourth bridge circuits 330 and 340 will be described in detail with reference to FIG. 21 and FIG. 22. FIG. 21 is an explanatory diagram showing directions of the magnetization of the magnetization pinned layers 52 in the first and third resistor sections of each of the first to fourth bridge circuits 310, 320, 330, and 340. FIG. 22 is an explanatory diagram showing directions of the magnetization of the magnetization pinned layers 52 in the second and fourth resistor sections of each of the first to fourth bridge circuits 310, 320, 330, and 340.

Each of the third bridge circuit 330 and the fourth bridge circuit 340 may be disposed at a position different from the positions of the first bridge circuit 310, the second bridge circuit 320, the plurality of first yokes 40A, the plurality of second yokes 40B, and the plurality of third yokes 40C, in the direction parallel to the Z direction. In the example embodiment, in particular, the third bridge circuit 330 is disposed below the plurality of second yokes 40B. In other words, the third bridge circuit 330 is disposed so that the plurality of second yokes 40B are interposed between the third bridge circuit 330 and the first bridge circuit 310. The fourth bridge circuit 340 is disposed above the plurality of third yokes 40C. In other words, the fourth bridge circuit 340 is disposed so that the plurality of third yokes 40C are interposed between the fourth bridge circuit 340 and the second bridge circuit 320.

Note that the magnetic sensor 3 according to the example embodiment may include the shields 61 and 62 in the fourth example embodiment, or does not have to include them. When the magnetic sensor 3 includes the shields 61 and 62, the third bridge circuit 330 is disposed between the plurality of second yokes 40B and the shield 61, and the fourth bridge circuit 340 is disposed between the plurality of third yokes 40C and the shield 62.

The positional relationship between the plurality of MR elements 50C of the third bridge circuit 330 and the plurality of second yokes 40B is the same as that between the plurality of MR elements 50A of the first bridge circuit 310 and the plurality of first yokes 40A. The positional relationship between the plurality of MR elements 50D of the fourth bridge circuit 340 and the plurality of third yokes 40C is the same as that between the plurality of MR elements 50B of the second bridge circuit 320 and the plurality of first yokes 40A.

The third wiring 331 of the third bridge circuit 330 includes a plurality of third leads. The connection relationship between the plurality of MR elements 50C and the plurality of third leads is the same as the connection relationship between the plurality of MR elements 50A and the plurality of leads 12 (connection relationship between the plurality of MR elements 50B and the plurality of leads 22). Although not shown, the overall shape of the third wiring 331 may be a meandering shape, similarly to the first and second wirings 311 and 321.

The fourth wiring 341 of the fourth bridge circuit 340 includes a plurality of fourth leads. The connection relationship between the plurality of MR elements 50D and the plurality of fourth leads is the same as the connection relationship between the plurality of MR elements 50A and the plurality of leads 12 (connection relationship between the plurality of MR elements 50B and the plurality of leads 22). Although not shown, the overall shape of the fourth wiring 341 may be a meandering shape, as with the first and second wirings 311 and 321.

Next, the direction of the magnetization of the magnetization pinned layer 52 of the MR element 50 will be described. First, the direction of the magnetization of the magnetization pinned layer 52 in each of the first and third resistor sections R71 and R73 of the third bridge circuit 330 and the direction of the magnetization of the magnetization pinned layer 52 in each of the first and third resistor sections R81 and R83 of the fourth bridge circuit 340 will be described with reference to FIG. 21.

In the first and third resistor sections R71 and R73 in the third bridge circuit 330, the magnetization of the magnetization pinned layer 52 of the MR element 50C (first MR element), which is disposed near the first end face 40c of each of the plurality of second yokes 40B, of the plurality of MR elements 50C, includes a component in the first magnetization direction (X direction). The magnetization of the magnetization pinned layer 52 of the MR element 50C (second MR element), which is disposed near the second end face 40d of each of the plurality of second yokes 40B, of the plurality of MR elements 50C, includes a component in the second magnetization direction (−X direction).

In the first and third resistor sections R81 and R83 in the fourth bridge circuit 340, the magnetization of the magnetization pinned layer 52 of the MR element 50D (first MR element), which is disposed near the first end face 40c of each of the plurality of third yokes 40C, of the plurality of MR elements 50D, includes a component in the second magnetization direction (−X direction). The magnetization of the magnetization pinned layer 52 of the MR element 50D (second MR element), which is disposed near the second end face 40d of each of the plurality of third yokes 40C, of the plurality of MR elements 50D, includes a component in the first magnetization direction (X direction).

Next, the direction of the magnetization of the magnetization pinned layer 52 in each of the second and fourth resistor sections R72 and R74 of the third bridge circuit 330 and the direction of the magnetization of the magnetization pinned layer 52 in each of the second and fourth resistor sections R82 and R84 of the fourth bridge circuit 340 will be described with reference to FIG. 22.

In the second and fourth resistor sections R72 and R74 in the third bridge circuit 330, the magnetization of the magnetization pinned layer 52 of the MR element 50C (first MR element), which is disposed near the first end face 40c of each of the plurality of second yokes 40B, of the plurality of MR elements 50C, includes a component in the second magnetization direction (−X direction). The magnetization of the magnetization pinned layer 52 of the MR element 50C (second MR element), which is disposed near the second end face 40d of each of the plurality of second yokes 40B, of the plurality of MR elements 50C, includes a component in the first magnetization direction (X direction).

In the second and fourth resistor sections R82 and R84 of the fourth bridge circuit 340, the magnetization of the magnetization pinned layer 52 of the MR element 50D (first MR element), which is disposed near the first end face 40c of each of the plurality of third yokes 40C, of the plurality of MR elements 50D, includes a component in the first magnetization direction (X direction). The magnetization of the magnetization pinned layer 52 of the MR element 50D (second MR element), which is disposed near the second end face 40d of each of the plurality of third yokes 40C, of the plurality of MR elements 50D, includes a component in the second magnetization direction (X direction).

As shown in FIG. 21 and FIG. 22, the magnetization of the magnetization pinned layer 52 of the MR element 50A of the first bridge circuit 310, which is disposed near the first end face 40c of the first yoke 40A, and the magnetization of the magnetization pinned layer 52 of the MR element 50C of the third bridge circuit 330, which is disposed near the second end face 40d of the second yoke 40B, include the components in the directions opposite to each other. Note that the two MR elements 50A and 50C may be disposed so as to overlap each other when viewed in the Z direction.

Similarly, the magnetization of the magnetization pinned layer 52 of the MR element 50A of the first bridge circuit 310, which is disposed near the second end face 40d of the first yoke 40A, and the magnetization of the magnetization pinned layer 52 of the MR element 50C of the third bridge circuit 330, which is disposed near the first end face 40c of the second yoke 40B, include the components in the directions opposite to each other. Note that the two MR elements 50A and 50C may be disposed so as to overlap each other when viewed in the Z direction.

As shown in FIG. 21 and FIG. 22, the magnetization of the magnetization pinned layer 52 of the MR element 50B of the second bridge circuit 320, which is disposed near the first end face 40c of the first yoke 40A, and the magnetization of the magnetization pinned layer 52 of the MR element 50D of the fourth bridge circuit 340, which is disposed near the second end face 40d of the third yoke 40C, include the components in the directions opposite to each other. Note that the two MR elements 50B and 50D may be disposed so as to overlap each other when viewed in the Z direction.

Similarly, the magnetization of the magnetization pinned layer 52 of the MR element 50B of the second bridge circuit 320, which is disposed near the second end face 40d of the first yoke 40A, and the magnetization of the magnetization pinned layer 52 of the MR element 50D of the fourth bridge circuit 340, which is disposed near the first end face 40c of the third yoke 40C, include the components in the directions opposite to each other. Note that the two MR elements 50B and 50D may be disposed so as to overlap each other when viewed in the Z direction.

Next, two detection signals generated by each of the third bridge circuit 330 and the fourth bridge circuit 340 will be described with reference to FIG. 20 to FIG. 22. The third bridge circuit 330 will be described first. The third bridge circuit 330 alone is configured to generate two detection signals corresponding to the magnetic field component in the direction parallel to the Z direction, similarly to the first bridge circuit 310. The foregoing description of the first bridge circuit 310 in the third example embodiment also applies to the third bridge circuit 330.

The aspect of the changes in the resistances of the respective first to fourth resistor sections R71 to R74 in the case where the direction of the input magnetic field component is in the Z direction is the same as that of the changes in the resistances of the respective first to fourth resistor sections R51 to R54 of the first bridge circuit 310 in the case where the direction of the input magnetic field component is in the Z direction. In addition, the aspect of the changes in the resistances of the respective first to fourth resistor sections R71 to R74 in the case where the direction of the input magnetic field component is in the −Z direction is the same as that of the changes in the resistances of the respective first to fourth resistor sections R51 to R54 in the case where the direction of the input magnetic field component is in the −Z direction.

Next, the fourth bridge circuit 340 will be described. The fourth bridge circuit 340 alone is configured to generate two detection signals corresponding to the magnetic field component in the direction parallel to the Z direction, similarly to the second bridge circuit 320. The foregoing description on the second bridge circuit 320 in the third example embodiment is basically applied also to the fourth bridge circuit 340.

The aspect of the changes in the resistances of the respective first to fourth resistor sections R81 to R84 in the case where the direction of the input magnetic field component is in the Z direction is the same as that of the changes in the resistances of the respective first to fourth resistor sections R61 to R64 of the second bridge circuit 320 in the case where the direction of the input magnetic field component is in the Z direction. In addition, the aspect of the changes in the resistances of the respective first to fourth resistor sections R81 to R84 in the case where the direction of the input magnetic field component is in the −Z direction is the same as that of the changes in the resistances of the respective first to fourth resistor sections R61 to R64 in the case where the direction of the input magnetic field component is in the −Z direction.

Next, at least one detection signal generated by the magnetic sensor 3 according to the example embodiment will be described. The connection point P53 of the first bridge circuit 310, the connection point P63 of the second bridge circuit 320, the connection point P73 of the third bridge circuit 330, and the connection point P83 of the fourth bridge circuit 340 are connected to the first signal output terminal E31. The connection point P54 of the first bridge circuit 310, the connection point P64 of the second bridge circuit 320, the connection point P74 of the third bridge circuit 330, and the connection point P84 of the fourth bridge circuit 340 are connected to the second signal output terminal E32. In the example embodiment, the potential at each of the connection points P53, P63, P73, and P83 and the potential at the first signal output terminal E31 are equal to each other, and the potential at each of the connection points P54, P64, P74, and P84 and the potential at the second signal output terminal E32 are equal to each other. The potential at each of the first and second signal output terminals E31 and E32 changes in the similar manner as the potential at each of the connection points P53 and P54 in the case of the first bridge circuit 310 alone, the potential at each of the connection points P63 and P64 in the case of the second bridge circuit 320 alone, the potential at each of the connection points P73 and P74 in the case of the third bridge circuit 330 alone, or the potential at each of the connection points P83 and P84 in the case of the fourth bridge circuit 340 alone. The magnetic sensor 3 generates, as at least one detection signal, a signal corresponding to the potential at each of the first and second signal output terminals E31 and E32 or corresponding to a potential difference between the first and second signal output terminals E31 and E32. The at least one detection signal has a correspondence with the magnetic field component of the magnetic field to be detected in the Z direction.

The configuration, operation, and effects of the example embodiment are otherwise the same as those of the third or fourth example embodiment.

### Modification Example

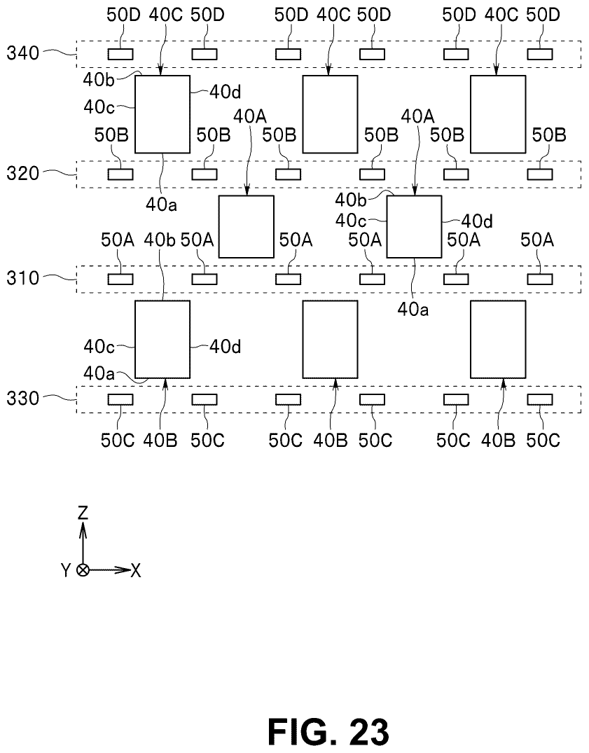

Next, a modification example of the magnetic sensor 3 according to the example embodiment will be described with reference to FIG. 23. FIG. 23 is a side view showing a part of the modification example of the magnetic sensor 3. In the modification example, the dimension of each of the plurality of second yokes 40B in the direction parallel to the Z direction and the dimension of each of the plurality of third yokes 40C in the direction parallel to the Z direction may be larger than the dimension of each of the plurality of first yokes 40A in the direction parallel to the Z direction. The dimension of each of the plurality of second yokes 40B in the direction parallel to the Z direction and the dimension of each of the plurality of third yokes 40C in the direction parallel to the Z direction may be the same or may be different from each other.

In some cases, the strength of the output magnetic field component applied to the plurality of MR elements 50C of the third bridge circuit 330 becomes smaller than the strength of the output magnetic field component applied to the plurality of MR elements 50A of the first bridge circuit 310. According to the modification example, increasing the dimension of each of the plurality of second yokes 40B in the direction parallel to the Z direction enables the strength of the output magnetic field component applied to the plurality of MR elements 50C to be increased.

Similarly, in some cases, the strength of the output magnetic field component applied to the plurality of MR elements 50D of the fourth bridge circuit 340 becomes smaller than the strength of the output magnetic field component applied to the plurality of MR elements 50B of the second bridge circuit 320. According to the modification example, increasing the dimension of each of the plurality of third yokes 40C in the direction parallel to the Z direction enables the strength of the output magnetic field component applied to the plurality of MR elements 50D to be increased.

### Sixth Example Embodiment

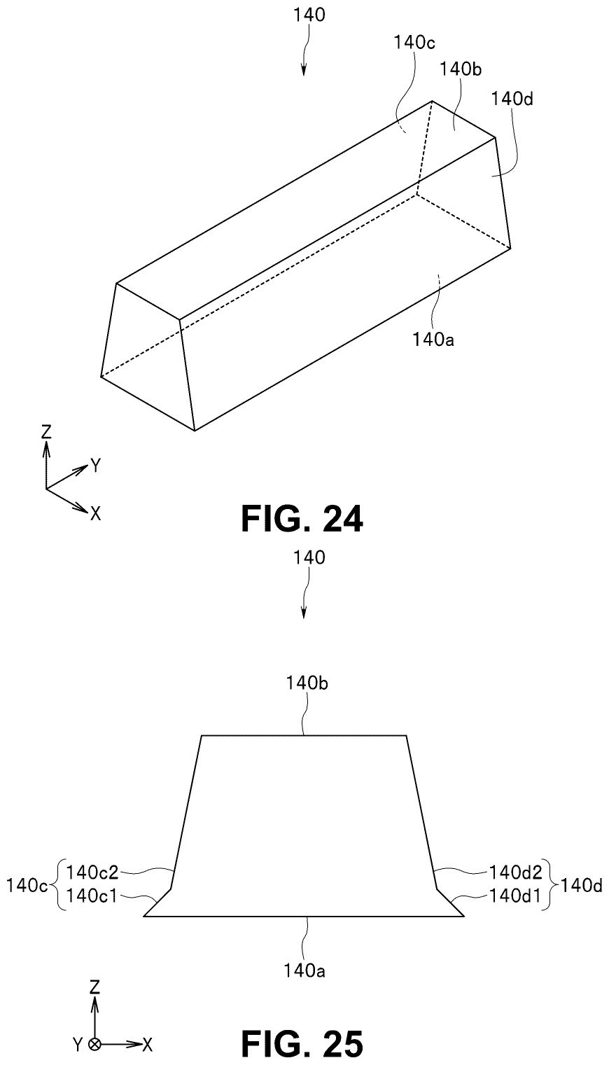

A sixth example embodiment of the disclosure will now be described. First, a yoke in the example embodiment will be described with reference to FIG. 24. FIG. 24 is a perspective view showing the yoke in the example embodiment.

A yoke 140 in the example embodiment is formed of a soft magnetic material and configured to induce the magnetic field around the yoke 140. The yoke 140, similarly to the first yoke 40 in the first example embodiment, may be configured to increase the strength of the magnetic field component of the magnetic field to be detected in the X direction, the magnetic field to be detected being applied to the MR element 50. Alternatively, the yoke 140, similarly to the first yoke 40 in the third example embodiment, may be configured to induce the input magnetic field, which includes the input magnetic field component in the direction parallel to the Z direction, to generate an output magnetic field.

In the example shown in FIG. 24, the yoke 140 has a shape that is long in the direction parallel to the Y direction. In addition, the cross-sectional shape of the yoke 140 in the cross section parallel to an XZ plane is a trapezoidal shape.

The yoke 140 includes a bottom surface 140a and a top surface 140b that are located on opposite sides to each other in the direction parallel to the Z direction, and a first end face 140c and a second end face 140d that are located on opposite sides to each other in the direction parallel to the X direction. Each of the first end face 140c and the second end face 140d is inclined relative to the direction parallel to the Z direction. The distance between the first end face 140c and the second end face 140d in the direction parallel to the X direction decreases with increasing distance from the bottom surface 140a.

The yoke 140 may be used, instead of the first yoke 40 in the first example embodiment. In this case, the magnetic sensor 1 is provided with a plurality of yokes 140. The positional relationship between the plurality of yokes 140 and the plurality of MR elements 50 is the same as that between the plurality of first yokes 40 and the plurality of MR elements 50 in the first example embodiment.

Similarly, the yoke 140 may be used, instead of the first yoke 40 in the third example embodiment. In this case, the magnetic sensor 3 is provided with a plurality of yokes 140. The positional relationship between the plurality of yokes 140 and the plurality of MR elements 50 is the same as that between the plurality of first yokes 40 and the plurality of MR elements 50 in the third example embodiment.

Similarly, the yoke 140 may be used, instead of the first yoke 40A, the second yoke 40B, and the third yoke 40C in the fourth or fifth example embodiment. In this case, the magnetic sensor 3 is provided with a plurality of yokes 140. The positional relationship between the plurality of yokes 140 used instead of the plurality of first yokes 40A and the plurality of MR elements 50 is the same as that between the plurality of first yokes 40A and the plurality of MR elements 50 in the fourth or fifth example embodiment. The positional relationship between the plurality of yokes 140 used instead of the plurality of second yokes 40B and the plurality of MR elements 50 is the same as that between the plurality of second yokes 40B and the plurality of MR elements 50 in the fourth or fifth example embodiment. The positional relationship between the plurality of yokes 140 used instead of the plurality of third yokes 40C and the plurality of MR elements 50 is the same as that between the plurality of third yokes 40C and the plurality of MR elements 50 in the fourth or fifth example embodiment.

In addition, the positional relationship among the plurality of yokes 140 used instead of the plurality of first yokes 40A, the plurality of yokes 140 used instead of the plurality of second yokes 40B, and the plurality of yokes 140 used instead of the plurality of third yokes 40C is the same as that among the plurality of first yokes 40A, the plurality of second yokes 40B, and the plurality of third yokes 40C in the fourth or fifth example embodiment.

Note that the plurality of yokes 140 may be used instead of one or two of the first yoke 40A, the second yoke 40B, and the third yoke 40C.

The plurality of yokes 140 may be used, instead of the plurality of first yokes 40 in the second example embodiment. In this case, each of the plurality of yokes 140 is provided in the orientation rotated from the orientation shown in FIG. 24 by 90 degrees around an axis parallel to the Z direction. The positional relationship between the plurality of yokes 140 and the plurality of MR elements 50 is the same as that between the plurality of first yokes 40 and the plurality of MR elements 50 in the second example embodiment.

Next, the effects of the example embodiment will be described. In general, the soft magnetic body such as a yoke is formed by plating, by using a photoresist mask having an opening portion formed on a seed layer. Therefore, due to the shape accuracy of the photoresist mask, the width of the yoke near the bottom surface of the yoke (the distance between the first end face and the second end face) may possibly become small or cause a variation in the shape of the yoke near the bottom surface of the yoke. As a result, the strength of the magnetic field to be applied to the MR element 50 disposed near the bottom surface of the yoke may possibly decrease or cause a variation in the strength of the magnetic field to be applied to the MR element 50.

To address these, according to the example embodiment, the cross-sectional shape of the yoke 140 is formed to be the trapezoidal shape, thereby preventing the decrease in the distance between the first end face 140c and the second end face 140d near the bottom surface 140a of the yoke 140 and suppressing the variation in the distance. As a result, according to the example embodiment, it is possible to prevent the decrease in the strength of the magnetic field to be applied to the MR element 50 disposed near the bottom surface 140a of the yoke 140 and suppress the variation in the strength of the magnetic field to be applied to the MR element 50.

In addition, according to the example embodiment, it is possible to make the distance between the top surfaces 140b of two yokes 140 adjacent at a distance from each other in the direction parallel to the X direction larger than the distance between the bottom surfaces 140a of the two yokes 140. Thus, according to the example embodiment, it is easier to form an insulating layer between the two yokes 140, and it is possible to make the distance between the two yokes 140 small. Consequently, according to the example embodiment, the occupancy area of the plurality of MR elements 50 can be increased.

The configuration, operation, and effects of the example embodiment are otherwise the same as those of any of the first to fifth example embodiments.

### Modification Example

Next, a modification example of the yoke 140 in the example embodiment will be described with reference to FIG. 25. FIG. 25 is a side view showing a modification example of the yoke 140. In the modification example, the first end face 140c of the yoke 140 includes a first part 140cl connected to the bottom surface 140a, and a second part 140c2 that connects the first part 140cl and the top surface 140b. The second end face 140d of the yoke 140 includes a first part 140dl connected to the bottom surface 140a, and a second part 140d2 that connects the first part 140dl and the top surface 140b.

An angle that the first part 140cl of the first end face 140c forms with respect to the direction parallel to the Z direction is larger than an angle that the second part 140c2 of the first end face 140c forms with respect to the direction parallel to the Z direction. An angle that the first part 140d1 of the second end face 140d forms with respect to the direction parallel to the Z direction is larger than an angle that the second part 140d2 of the second end face 140d forms with respect to the direction parallel to the Z direction.

Note that the disclosure is not limited to each of the foregoing example embodiments, and various modifications may be made thereto. For example, as long as the requirements of the appended claims are met, the layout of the first to fourth resistor sections is not limited to the example shown in each of the example embodiments and it is optional. For example, the first resistor section of the first bridge circuit and the third resistor section of the second bridge circuit may be disposed so as to overlap each other when viewed in the Z direction, the second resistor section of the first bridge circuit and the fourth resistor section of the second bridge circuit may be disposed so as to overlap each other when viewed in the Z direction, the third resistor section of the first bridge circuit and the first resistor section of the second bridge circuit may be disposed so as to overlap each other when viewed in the Z direction, and the fourth resistor section of the first bridge circuit and the second resistor section of the second bridge circuit may be disposed so as to overlap each other when viewed in the Z direction.

In the magnetic sensor 3 according to the fifth example embodiment, only one of the third bridge circuit 330 and the fourth bridge circuit 340 may be provided.

Furthermore, each of the magnetic sensor 1 according to the first example embodiment, the magnetic sensor 2 according to the second example embodiment, and the magnetic sensor 3 according to the third example embodiment may include the at least one shield in the fourth example embodiment.

A magnetic sensor device for detecting geomagnetism may be provided with the magnetic sensor 1 according to the first example embodiment, the magnetic sensor 2 according to the second example embodiment, and the magnetic sensor 3 according to any one of the third to fifth example embodiments.

As described above, a magnetic sensor according to one embodiment of the disclosure includes: a plurality of yokes each formed of a soft magnetic material; a plurality of magnetoresistive elements configured to detect a magnetic field induced by the plurality of yokes; and a plurality of bridge circuits constituted of the plurality of magnetoresistive elements, each of the plurality of bridge circuits being configured to generate at least one detection signal. The plurality of yokes include a plurality of first yokes disposed at a same position in a first direction. The plurality of bridge circuits include a first bridge circuit and a second bridge circuit that are disposed at positions different from each other in the first direction, and disposed so that the plurality of first yokes are interposed between the first bridge circuit and the second bridge circuit. The first bridge circuit and the second bridge circuit are connected in parallel with each other.

In the magnetic sensor according to one embodiment of the disclosure, each of the plurality of first yokes may have a first end face and a second end face that are located on opposite sides to each other in a second direction orthogonal to the first direction. The plurality of magnetoresistive elements may include a plurality of element pairs. Each of the plurality of element pairs may include a first element disposed near the first end face of one of the plurality of first yokes, and a second element disposed near the second end face of the one of the plurality of first yokes. Each of the first bridge circuit and the second bridge circuit may include a lead configured to electrically connect the first element and the second element, the lead including a part overlapping the one of the plurality of first yokes when viewed in the first direction.

In the magnetic sensor according to one embodiment of the disclosure, each of the plurality of magnetoresistive elements may include a magnetization pinned layer, a direction of a magnetization of the magnetization pinned layer being fixed, and a free layer, a direction of a magnetization of the free layer being variable depending on a magnetic field to be applied. The plurality of first yokes may include a specific yoke. The magnetization of the magnetization pinned layer of the first element, which is disposed near the first end face of the specific yoke, in the first bridge circuit, and the magnetization of the magnetization pinned layer of the second element, which is disposed near the second end face of the specific yoke, in the second bridge circuit, may each include a component in a first magnetization direction. The magnetization of the magnetization pinned layer of the second element, which is disposed near the second end face of the specific yoke, in the first bridge circuit, and the magnetization of the magnetization pinned layer of the first element, which is disposed near the first end face of the specific yoke, in the second bridge circuit, may each include a component in a second magnetization direction opposite the first magnetization direction.

In the magnetic sensor according to one embodiment of the disclosure, the plurality of yokes may further include a plurality of second yokes and a plurality of third yokes that are disposed so that the plurality of first yokes are interposed between the plurality of second yokes and the plurality of third yokes. The plurality of second yokes may be disposed at a same position in the first direction. The plurality of third yokes may be disposed at a same position in the first direction. The first bridge circuit may be disposed between the plurality of first yokes and the plurality of second yokes. The second bridge circuit may be disposed between the plurality of first yokes and the plurality of third yokes. The plurality of first yokes does not have to overlap the plurality of second yokes and the plurality of third yokes when viewed in the first direction. The plurality of bridge circuits may further include a third bridge circuit disposed at a position different from positions of the first bridge circuit, the second bridge circuit, the plurality of first yokes, the plurality of second yokes, and the plurality of third yokes, in the first direction.

In addition, when the plurality of yokes include the plurality of second yokes and the plurality of third yokes, the first bridge circuit may be disposed between the plurality of first yokes and the plurality of second yokes. The second bridge circuit may be disposed between the plurality of first yokes and the plurality of third yokes. The plurality of bridge circuits may further include a third bridge circuit disposed so that the plurality of second yokes are interposed between the third bridge circuit and the first bridge circuit, and a fourth bridge circuit disposed so that the plurality of third yokes are interposed between the fourth bridge circuit and the second bridge circuit. A dimension of each of the plurality of second yokes in the first direction and a dimension of each of the plurality of third yokes in the first direction may be larger than a dimension of each of the plurality of first yokes in the first direction.

The magnetic sensor according to one embodiment of the disclosure may include a plurality of connection electrodes each extending in the first direction. A layout of a plurality of first elements, which are included in the first bridge circuit, of the plurality of magnetoresistive elements, and a layout of a plurality of second elements, which are included in the second bridge circuit, of the plurality of magnetoresistive elements may be the same. The first bridge circuit may include a first wiring that electrically connects the plurality of first elements. The second bridge circuit may include a second wiring that electrically connects the plurality of second elements. The plurality of connection electrodes may electrically connect the first wiring and the second wiring. The magnetic sensor according to one embodiment of the disclosure may further include a power supply terminal, a ground terminal, and at least one signal output terminal. A number of the plurality of connection electrodes may be equal to a total number of the power supply terminal, the ground terminal, and the at least one signal output terminal.

The magnetic sensor according to one embodiment of the disclosure may further include a first terminal and a second terminal. Each of the first bridge circuit and the second bridge circuit may include a resistor section disposed between the first terminal and the second terminal. The resistor section of the first bridge circuit and the resistor section of the second bridge circuit may be disposed so as to overlap each other when viewed in the first direction. Each of the plurality of first yokes may have a first end face and a second end face that are located on opposite sides to each other in a second direction orthogonal to the first direction. The plurality of magnetoresistive elements may include a plurality of element pairs. Each of the plurality of element pairs may include a first element which is disposed near the first end face of one of the plurality of first yokes, and a second element which is disposed near the second end face of the one of the plurality of first yokes. Each of the plurality of magnetoresistive elements may include a magnetization pinned layer, a direction of a magnetization of the magnetization pinned layer being fixed, and a free layer, a direction of a magnetization of the free layer being variable depending on a magnetic field to be applied. The magnetization of the magnetization pinned layer of the first element in the resistor section of the first bridge circuit and the magnetization of the magnetization pinned layer of the second element in the resistor section of the second bridge circuit may each include a component in a first magnetization direction. The magnetization of the magnetization pinned layer of the second element in the resistor section of the first bridge circuit and the magnetization of the magnetization pinned layer of the first element in the resistor section of the second bridge circuit may each include a component in a second magnetization direction opposite the first magnetization direction.

The magnetic sensor according to one embodiment of the disclosure may further include a power supply terminal, a ground terminal, and a signal output terminal. Each of the first bridge circuit and the second bridge circuit may include a first resistor section disposed between the power supply terminal and the signal output terminal, and a second resistor section disposed between the ground terminal and the signal output terminal. Each of the plurality of first yokes may have a first end face and a second end face that are located on opposite sides to each other in a second direction orthogonal to the first direction. The plurality of magnetoresistive elements may include a plurality of element pairs. Each of the plurality of element pairs may include a first element which is disposed near the first end face of one of the plurality of first yokes, and a second element which is disposed near the second end face of the one of the plurality of first yokes. Each of the plurality of magnetoresistive elements may include a magnetization pinned layer, a direction of a magnetization of the magnetization pinned layer being fixed, and a free layer, a direction of a magnetization of the free layer being variable depending on a magnetic field to be applied. The magnetization of the magnetization pinned layer of the first element in the first resistor section of one bridge circuit of the first bridge circuit and the second bridge circuit, and the magnetization of the magnetization pinned layer of the second element in the second resistor section of the one bridge circuit, may each include a component in a first magnetization direction. The magnetization of the magnetization pinned layer of the second element in the first resistor section of the one bridge circuit and the magnetization of the magnetization pinned layer of the first element in the second resistor section of the one bridge circuit may each include a component in a second magnetization direction opposite the first magnetization direction.

The magnetic sensor according to one embodiment of the disclosure may further include at least one shield disposed so as to overlap the plurality of bridge circuits when viewed in the first direction.

A manufacturing method for the magnetic sensor according to one embodiment of the disclosure includes forming the plurality of magnetoresistive elements. The forming the plurality of magnetoresistive elements includes: forming a plurality of initial magnetoresistive elements each including an initial magnetization pinned layer to later become the magnetization pinned layer, and the free layer; forming a plurality of first type of elements by fixing a direction of a magnetization of the initial magnetization pinned layer in some of the plurality of initial magnetoresistive elements by using laser light and a first external magnetic field including a component in a first magnetic field direction; and forming a plurality of second type of elements by fixing a direction of a magnetization of the initial magnetization pinned layer in some others of the plurality of initial magnetoresistive elements by using laser light and a second external magnetic field including a component in a second magnetic field direction.

A manufacturing method for the magnetic sensor according to one embodiment of the disclosure includes forming the plurality of magnetoresistive elements. The forming the plurality of magnetoresistive elements includes: forming a plurality of initial magnetoresistive elements each including an initial magnetization pinned layer to later become the magnetization pinned layer, and the free layer, and performing annealing treatment of heating the plurality of initial magnetoresistive elements at a specific temperature while applying an external magnetic field in one direction parallel to the first direction so that a direction of a magnetization of the initial magnetization pinned layer is fixed.

In the magnetic sensor of the disclosure, the first bridge circuit and the second bridge circuit are disposed at positions different from each other in the first direction, and disposed so that the plurality of first yokes are interposed between the first bridge circuit and the second bridge circuit. The first bridge circuit and the second bridge circuit are connected in parallel with each other. With such a configuration, according to the disclosure, the occupancy area of the magnetoresistive elements can be increased while reducing the resistances of the wirings that electrically connect the plurality of magnetoresistive elements.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A magnetic sensor comprising:
a plurality of yokes each formed of a soft magnetic material;
a plurality of magnetoresistive elements configured to detect a magnetic field induced by the plurality of yokes; and
a plurality of bridge circuits constituted of the plurality of magnetoresistive elements, and configured to generate at least one detection signal, wherein
the plurality of yokes include a plurality of first yokes disposed at a same position in a first direction,
the plurality of bridge circuits include a first bridge circuit and a second bridge circuit that are disposed at positions different from each other in the first direction, and disposed so that the plurality of first yokes are interposed between the first bridge circuit and the second bridge circuit, and
the first bridge circuit and the second bridge circuit are connected in parallel with each other.

2. The magnetic sensor according to claim 1, wherein:
each of the plurality of first yokes has a first end face and a second end face that are located on opposite sides to each other in a second direction orthogonal to the first direction;
the plurality of magnetoresistive elements include a plurality of element pairs;
each of the plurality of element pairs includes a first element disposed near the first end face of one of the plurality of first yokes, and a second element disposed near the second end face of the one of the plurality of first yokes; and
each of the first bridge circuit and the second bridge circuit includes a lead configured to electrically connect the first element and the second element, the lead including a part overlapping the one of the plurality of first yokes when viewed in the first direction.

3. The magnetic sensor according to claim 2, wherein:
each of the plurality of magnetoresistive elements includes a magnetization pinned layer, a direction of a magnetization of the magnetization pinned layer being fixed, and a free layer, a direction of a magnetization of the free layer being variable depending on a magnetic field to be applied;
the plurality of first yokes include a specific yoke;
the magnetization of the magnetization pinned layer of the first element, which is disposed near the first end face of the specific yoke, in the first bridge circuit, and the magnetization of the magnetization pinned layer of the second element, which is disposed near the second end face of the specific yoke, in the second bridge circuit, each include a component in a first magnetization direction; and
the magnetization of the magnetization pinned layer of the second element, which is disposed near the second end face of the specific yoke, in the first bridge circuit, and the magnetization of the magnetization pinned layer of the first element, which is disposed near the first end face of the specific yoke, in the second bridge circuit, each include a component in a second magnetization direction opposite the first magnetization direction.

4. The magnetic sensor according to claim 1, wherein:
the plurality of yokes further include a plurality of second yokes and a plurality of third yokes that are disposed so that the plurality of first yokes are interposed between the plurality of second yokes and the plurality of third yokes;
the plurality of second yokes are disposed at a same position in the first direction; and
the plurality of third yokes are disposed at a same position in the first direction.

5. The magnetic sensor according to claim 4, wherein:
the first bridge circuit is disposed between the plurality of first yokes and the plurality of second yokes; and
the second bridge circuit is disposed between the plurality of first yokes and the plurality of third yokes.

6. The magnetic sensor according to claim 5, wherein the plurality of first yokes does not overlap the plurality of second yokes and the plurality of third yokes when viewed in the first direction.

7. The magnetic sensor according to claim 4, wherein the plurality of bridge circuits further include a third bridge circuit disposed at a position different from positions of the first bridge circuit, the second bridge circuit, the plurality of first yokes, the plurality of second yokes, and the plurality of third yokes, in the first direction.

8. The magnetic sensor according to claim 4, wherein:
the first bridge circuit is disposed between the plurality of first yokes and the plurality of second yokes;
the second bridge circuit is disposed between the plurality of first yokes and the plurality of third yokes; and
the plurality of bridge circuits further include a third bridge circuit disposed so that the plurality of second yokes are interposed between the third bridge circuit and the first bridge circuit, and a fourth bridge circuit disposed so that the plurality of third yokes are interposed between the fourth bridge circuit and the second bridge circuit.

9. The magnetic sensor according to claim 4, wherein a dimension of each of the plurality of second yokes in the first direction and a dimension of each of the plurality of third yokes in the first direction are larger than a dimension of each of the plurality of first yokes in the first direction.

10. The magnetic sensor according to claim 1, further comprising,
a plurality of connection electrodes each extending in the first direction, wherein:
a layout of a plurality of first elements, which are included in the first bridge circuit, of the plurality of magnetoresistive elements, and a layout of a plurality of second elements, which are included in the second bridge circuit, of the plurality of magnetoresistive elements are the same;
the first bridge circuit includes a first wiring that electrically connects the plurality of first elements;
the second bridge circuit includes a second wiring that electrically connects the plurality of second elements; and
the plurality of connection electrodes electrically connect the first wiring and the second wiring.

11. The magnetic sensor according to claim 10, further comprising:
a power supply terminal;
a ground terminal; and
at least one signal output terminal, wherein
a number of the plurality of connection electrodes is equal to a total number of the power supply terminal, the ground terminal, and the at least one signal output terminal.

12. The magnetic sensor according to claim 1, further comprising:
a first terminal; and
a second terminal, wherein:
each of the first bridge circuit and the second bridge circuit includes a resistor section disposed between the first terminal and the second terminal;
the resistor section of the first bridge circuit and the resistor section of the second bridge circuit are disposed so as to overlap each other when viewed in the first direction;
each of the plurality of first yokes has a first end face and a second end face that are located on opposite sides to each other in a second direction orthogonal to the first direction;
the plurality of magnetoresistive elements include a plurality of element pairs;
each of the plurality of element pairs includes a first element which is disposed near the first end face of one of the plurality of first yokes, and a second element which is disposed near the second end face of the one of the plurality of first yokes;
each of the plurality of magnetoresistive elements includes a magnetization pinned layer, a direction of a magnetization of the magnetization pinned layer being fixed, and a free layer, a direction of a magnetization of the free layer being variable depending on a magnetic field to be applied;
the magnetization of the magnetization pinned layer of the first element in the resistor section of the first bridge circuit and the magnetization of the magnetization pinned layer of the second element in the resistor section of the second bridge circuit each include a component in a first magnetization direction; and
the magnetization of the magnetization pinned layer of the second element in the resistor section of the first bridge circuit and the magnetization of the magnetization pinned layer of the first element in the resistor section of the second bridge circuit each include a component in a second magnetization direction opposite the first magnetization direction.

13. The magnetic sensor according to claim 1, further comprising:
a power supply terminal;
a ground terminal; and
a signal output terminal, wherein:
each of the first bridge circuit and the second bridge circuit includes a first resistor section disposed between the power supply terminal and the signal output terminal, and a second resistor section disposed between the ground terminal and the signal output terminal;
each of the plurality of first yokes has a first end face and a second end face that are located on opposite sides to each other in a second direction orthogonal to the first direction;
the plurality of magnetoresistive elements include a plurality of element pairs;
each of the plurality of element pairs includes a first element which is disposed near the first end face of one of the plurality of first yokes, and a second element which is disposed near the second end face of the one of the plurality of first yokes;
each of the plurality of magnetoresistive elements includes a magnetization pinned layer, a direction of a magnetization of the magnetization pinned layer being fixed, and a free layer, a direction of a magnetization of the free layer being variable depending on a magnetic field to be applied;
the magnetization of the magnetization pinned layer of the first element in the first resistor section of one bridge circuit of the first bridge circuit and the second bridge circuit, and the magnetization of the magnetization pinned layer of the second element in the second resistor section of the one bridge circuit, each include a component in a first magnetization direction; and
the magnetization of the magnetization pinned layer of the second element in the first resistor section of the one bridge circuit and the magnetization of the magnetization pinned layer of the first element in the second resistor section of the one bridge circuit each include a component in a second magnetization direction opposite the first magnetization direction.

14. The magnetic sensor according to claim 1, further comprising at least one shield disposed so as to overlap the plurality of bridge circuits when viewed in the first direction.

15. A manufacturing method for the magnetic sensor according to claim 1,
wherein each of the plurality of magnetoresistive elements includes a magnetization pinned layer, a direction of a magnetization of the magnetization pinned layer being fixed, and a free layer, a direction of a magnetization of the free layer being variable depending on a magnetic field to be applied,
the plurality of magnetoresistive elements include a plurality of first type of elements and a plurality of second type of elements,
the magnetization of the magnetization pinned layer in the plurality of first type of elements includes a component in a first magnetization direction, and
the magnetization of the magnetization pinned layer in the plurality of second type of elements includes a component in a second magnetization direction opposite the first magnetization direction,
wherein the manufacturing method comprises forming the plurality of magnetoresistive elements, and
the forming the plurality of magnetoresistive elements includes:
forming a plurality of initial magnetoresistive elements each including an initial magnetization pinned layer to later become the magnetization pinned layer, and the free layer;
forming the plurality of first type of elements by fixing a direction of a magnetization of the initial magnetization pinned layer in some of the plurality of initial magnetoresistive elements by using laser light and a first external magnetic field including a component in a first magnetic field direction; and
forming the plurality of second type of elements by fixing a direction of a magnetization of the initial magnetization pinned layer in some others of the plurality of initial magnetoresistive elements by using laser light and a second external magnetic field including a component in a second magnetic field direction.

16. A manufacturing method for the magnetic sensor according to claim 1,
wherein each of the plurality of magnetoresistive elements includes a magnetization pinned layer, a direction of a magnetization of the magnetization pinned layer being fixed, and a free layer, a direction of a magnetization of the free layer being variable depending on a magnetic field to be applied, and
wherein the manufacturing method comprises forming the plurality of magnetoresistive elements, and
the forming the plurality of magnetoresistive elements includes:
forming a plurality of initial magnetoresistive elements each including an initial magnetization pinned layer to later become the magnetization pinned layer, and the free layer; and
performing annealing treatment of heating the plurality of initial magnetoresistive elements at a specific temperature while applying an external magnetic field in one direction parallel to the first direction so that a direction of a magnetization of the initial magnetization pinned layer is fixed.
